(19) United States
(12) Patent Application Publication
(10) Pub. No.: US 2025/0048709 A1
(43) Pub. Date: Feb. 6, 2025

(54) ELECTRONIC METADEVICE

(71) Applicant: ECOLE POLYTECHNIQUE FEDERALE DE LAUSANNE (EPFL), Lausanne (CH)

(72) Inventors: Mohammad SAMIZADEH NIKOOYTABALVANDANI, Lausanne (CH); Elison de Nazareth MATIOLI, Lausanne (CH)

(21) Appl. No.: 18/717,221

(22) PCT Filed: Dec. 9, 2022
(86) PCT No.: PCT/IB2022/061973

§ 371 Date: Jun. 6, 2024

(30) Foreign Application Priority Data
Dec. 9, 2021 (WO) PCT/IB2021/061513

(51) Int. Cl. H01L 29/41; H01L 29/20; H01L 29/417; H01L 29/778; H01L 29/86

(52) U.S. Cl. CPC H01L 29/413; H01L 29/41725; H01L 29/20; H01L 29/778; H01L 29/86

(57) ABSTRACT

Electronic metadevice comprising a conductive channel; a metal layer superposed on the conductive channel; and a barrier layer located between the metal layer and the conductive channel. The metal layer includes at least one recess extending through the metal layer to define at least one metallic metastructure comprising at least one first metal layer portion adjacent to at least one second metal layer portion. The recess extends through the metal layer to define a micro-structured or a nano-structured first metal layer portion comprising at least one first metallic extension or finger extending away from a first support of the first metal layer portion towards the second metal layer portion; and a micro-structured or a nano-structured at least one second metal layer portion comprising at least one second metallic extension or finger extending away from a second support of the second metal layer portion towards the first metal layer portion.

### CROSS-REFERENCE TO RELATED APPLICATIONS

The present application claims priority to International Patent Application PCT/IB2021/061513 filed on Dec. 9, 2021, the entire contents thereof being herewith incorporated by reference.

### FIELD OF THE INVENTION

The present invention relates to electronic devices and in particular relates to semiconductor devices, for example, semiconductor switches. The present invention relates to electronic metadevices and in particular electronic metadevices for terahertz applications.

### BACKGROUND

The evolution of electronics has largely relied on down scaling to meet the continuous needs for faster and highly integrated devices [1]. As the channel length is reduced, however, electronic devices face fundamental issues that hinder reaching the full materials potential and ultimately, further miniaturization [2]. For example, the carrier injection through tunneling junctions dominates the channel resistance [3], while the high parasitic capacitances drastically limit its maximum operating frequency [4]. In addition, such ultra-scaled devices can only hold a few volts due to the extremely high electric fields, which limits their maximum delivered power [5, 6].

Traditional electron devices such as transistors and diodes still perform inefficiently at high frequencies, much below than the potential enabled by the semiconductor materials. For example, 100-nm-long channel with a sheet resistance of 300Ω/ can potentially exhibit an ON resistance of R_{ON}=30Ω μm, which together with an approximate coplanar capacitance of 200 fF mm⁻¹ in the OFF state (C_{OFF}) would result in a cut-off frequency of over 20 THz. In addition, considering the high critical electric field of wide-band-gap semiconductors, such a device should be able to hold up to 20 V in the OFF state. These values are by far higher than those achieved by conventional high performance electronic devices up to date [6].

The minimum resistance between a metallic contact and a semiconducting channel with a carrier density of nₛ has a quantum limit of h/(2q²nₛ^{1/2}), where h is Planck's constant and q is the elementary charge. Considering nₛ=2×10¹³ cm⁻², the contact resistance (R_{C}) will be larger than ˜30Ω μm [3, 7, 8], which by itself is comparable with the resistance of the 100 nm-long semiconducting channel. The tunneling resistance becomes more dominant for electronic materials with higher electron mobilities that typically offer lower carrier densities, such InAs and InGaAs, which are more suitable for high speed applications [1]. In fact, achieving wafer-scale contact resistances below 100Ω μm on a high electron mobility platform is challenging, which makes the R_{C} the dominant factor limiting the total (trans)conductance of the device [9]. The contact resistance is also a serious limitation for electronics based on two-dimensional (2D) materials [10] and diamond [11].

While the conductance of semiconducting channels get totally dominated by the tunneling junctions, the OFF state performance of the devices worsens. This is due to the drastic increase in parasitic capacitance and also sharp interfaces which leads to breakdown voltage much below that the value imposed by the critical electric field of the material. The former limits the speed, and the latter limits the power handling and make the devices extremely vulnerable to electrostatic discharges and electromagnetic interferences [5, 12]. Exploiting the full potential of materials beyond the fundamental limitations of current electronic devices can enable variety of applications such as ultrahigh speed communications and imaging [13-17].

### SUMMARY

The present disclosure provides electronic devices that address the above-mentioned inconveniences and limitations of current devices.

The present disclosure provides the innovation of electronic devices or metadevices, based on collective and controllable electromagnetic interactions in deep-subwavelength scales enabled by electrical metastructures, which can overcome the theoretical limits of classical electron devices. This innovation is demonstrated using exemplary embodiments concerning microwave and terahertz switches, achieving very high cut-off frequencies, ultralow losses and large breakdown voltages. The innovation can be generally applied to any kind of semiconductor platform such as CMOS, III-V, wide-bandgap and two-dimensional materials. The devices of the present disclosure sets the stage for the next generation of high-performance semiconductor devices that exploit the full potential of electronic materials.

The present disclosure concerns electronic metadevices, in which the microscopic manipulation of radiofrequency fields results in extraordinary electronic properties. The devices operate based on electrostatic control of collective electromagnetic interactions in deep sub-wavelength scales, as an alternative to controlling the flow of electrons in traditional devices such as diodes and transistors. This enables a new class of electronic devices with cutoff frequency figure-of-merit well beyond ten terahertz, record high conductance values, extremely high breakdown voltages and picosecond switching speeds. This sets the stage for the next generation of ultrafast semiconductor devices, and present a new paradigm potentially bridging the gap between electronics and optics.

The principle is based on the subwavelength manipulation of electromagnetic fields which results in distinct macroscopic optical properties. The microscopic manipulation of radiofrequency fields leads to extraordinary macroscopic electronic device characteristics.

It is therefore one aspect of the present disclosure to provide an electronic metadevice according to claim 1.

Specific embodiments and other advantageous features can be found in the dependent claims.

The electronic metadevices of the present disclosure advantageously enable a microscopic manipulation of radiofrequency fields at will, resulting in electronic properties beyond the fundamental limitations of traditional semiconductor devices. Metastructures have revolutionized optics, enabling the realization of exotic media presenting functionalities beyond the material properties [18-21]. The present disclosure demonstrates innovative metastructures applied to electronics, enabling collective and controllable electromagnetic interactions in deep-subwavelength scales within the device. This results in outstanding properties that break some limitations of conventional electronics, leading to exceptionally high speeds, very low losses, and large delivered powers.

The above and other objects, features and advantages of the present invention and the manner of realizing them will become more apparent, and the invention itself will best be understood from a study of the following description with reference to the attached drawings showing some preferred embodiments of the invention.

### BRIEF DESCRIPTION OF THE DRAWINGS

The accompanying drawings, which are incorporated herein and constitute part of this specification, illustrate the presently preferred embodiments of the invention, and together with the general description given above and the detailed description given below, serve to explain features of the invention.

FIGS. 1A to 1K concerns a subwavelength TM mode on a (thin) metal-semiconductor barrier collectively interacting with a metastructure.

FIG. 1A is a schematic of a (thin) metal-insulator-semiconductor (MIS) structure including, what is considered for analysis purposes, a perfect electric conductor (PEC) layer separated by a dielectric barrier with a thickness d from the semiconducting channel.

FIG. 1B shows a wavelength versus frequency plot of an ordinary TEM mode (ρ/d→0 in Eq. 1) as well as the subwavelength TM mode (λ_{sub}). For the TM mode, the inventors assumed an effective d, considering the barrier thickness 10 nm as well as the skin effect on a non-ideal metal with a relative permeability of 600 (for Nickel).

FIG. 1C is an illustration of a MIS structure with a discontinuity on the top metal. The excited TM mode results in oscillatory fields close to the gap.

FIG. 1D shows an exemplary metadevice geometry according to the present disclosure on the similar MIS structure, in which instead of a straight gap, stripes with a subwavelength length are patterned. The gap length (g) is identical to the conventional device of FIG. 1C.

FIGS. 1E and 1F show simulated E_{z} at the barrier for a conventional device and a metadevice both with 500-nm-long gaps. One port is excited by a 1-V radiofrequency source and the other port is terminated by a 50-Ω load. The subwavelength radiofrequency field manipulation at 50 GHz for the metadevice results in outstanding electrical properties. Scale bars correspond to 2 μm.

FIG. 1G shows simulated E_{z} at the barrier along the propagation axis (x) at 50 GHz for conventional device and metadevice. The metadevice exhibits field continuity at the gap.

FIGS. 1H and 1I are illustrations of the electric field at the barrier for a conventional device and a metadevice, respectively. The vectorial integration of electric field for the metadevice just depends on the potential drop on the gap (ΔV_{gap}), showing an excellent coupling between the top metastructured pads and the semiconductor channel underneath.

FIGS. 1J and 1K show simulated current density at the semiconductor for the conventional device and the metadevice at 5 GHz and 50 GHz. The metadevice exhibits an extremely fine confinement of current at the gap resulting in an outstanding conductance. Scale bars correspond to 2 μm.

FIG. 1L schematically illustrates a MIS structure with a discontinuity on the top metal. The excited subwavelength mode results in oscillatory fields close to the gap. k_{c}² represents the square of the effective wavenumber of the mode.

FIG. 1M schematically shows a metadevice geometry on the same MIS structure, in which instead of a straight gap, stripes with a subwavelength length are patterned to form metastructures. The gap length (g) is identical to the straight-gap device. E_{z} satisfies the equation ∂²E_{z}/∂x²+kₘ²E_{z}=0, with kₘ being the effective wavenumber of the oscillatory subwavelength mode.

FIG. 1N shows simulated E_{z} at the barrier of an 8-nm-thin MIS structure of FIG. 1L with 100-nm-long gaps at 120 GHz.

FIG. 1O shows simulated E_{z} at the barrier of a metadevice of FIG. 1M with 100-nm-long gaps at 120 GHz.

FIG. 1P shows simulated E_{z} at the barrier along the propagation axis (x) for straight-gap (conventional) device and metadevice.

FIG. 1Q illustrates the electric field at the barrier for a metadevice (FIG. 1O). E_{z} has a lower intensity in an electronic metadevice comparing to that of a straight-gap device, and the polarity of E_{z} can be aligned in two adjacent stripes. In this case, the vectorial integration of electric field for the metadevice just depends on the potential drop on the gap.

FIGS. 1R and 1S show simulated semiconductor current density for the straight-gap device and the metadevice, showing a greater current confinement for the metadevice.

FIGS. 2A to 2F show electronic metadevices outperforming traditional devices.

FIG. 2A shows measured ON-state resistance and OFF-state capacitance of a 320-nm-long gap 100-μm-wide conventional metal-semiconductor-metal (MSM) switch, as well as the extracted cut-off frequency. The device has a threshold voltage of 3.5 V. The inset shows the device structure.

FIG. 2B is an illustration of the transition from a conventional straight-gap device to a metadevice, while keeping the device effective width constant. The stripes are 10-μm long.

FIG. 2C is an extracted cut-off frequency of the fabricated device with different stripe widths showing a notable increase of ˜3.7 time in cut-off frequency (f_{c}) for devices with 1.6-μm, 1.2-μm, and 0.8-μm-wide stripes.

FIG. 2D shows measured ON-state resistance and OFF-state impedance at 100 GHz for a metadevice with 8 stripes indicate an 8.1-THz cut-off frequency. The inset shows a scanning electron microscopy (SEM) image of the metadevice. The scale-bar corresponds to 4 μm.

FIG. 2E shows extracted contact resistance of conventional MSM device and a metadevice. The metadevice has 1.2-μm-wide stripes with 16 stripes. The conventional MSM device exhibits a contact resistance proportional to f^{1/2} as predicted by the theoretical description. The metadevice, however, shows a very steep reduction of contact resistance.

FIG. 2F shows a benchmark of the conventional MSM and the metadevice with mainstream electronic devices with metal and highly-doped semiconductor (semi-metal) contacts, considering R_{C} and R_{ON}.

FIGS. 3A to 3C show collective behavior of metadevices showing a superlinear conductance.

FIG. 3A shows conductance of metadevices with identical stripe shapes (1.2-μm width and 10-μm length) and different number of stripes. The results indicate a superlinear relation with respect to the number of stripes (scaling factor, S). This relation is linear for conventional devices, in which the scaling factor is considered to be proportional to the device width (S=W/W₀ with W₀=4 μm).

FIG. 3B shows cut-off frequency of conventional MSM devices as well as metadevice versus scaling factor.

FIG. 3C shows a benchmark of conventional MSM devices and metadevices with mainstream electron devices on a C_{OFF}-R_{ON} plane. All the characterizations were done at 50 GHz.

FIGS. 4A to 4C show conductance-versus-breakdown trade-off in metadevices.

FIG. 4A shows a breakdown test on metadevices with different gap distances, 220 nm, 320 nm, 420 nm, and 520 nm.

FIG. 4B shows breakdown voltage versus cut-off frequency in diodes and transistors, as well as metadevices. The results show that the proposed metadevice concept outperforms the state-of-the-art in mainstream electron devices.

FIG. 4C shows normalized conduction versus breakdown voltage for radiofrequency and power devices as well as metadevices. The proposed metadevice concept performance is very close to the ideal limit corresponding to the critical field of GaN and a sheet resistance of 300 Ω/.

FIGS. 5A to 5D show high-rate data transmission using metadevices.

FIG. 5A is a schematic of the experimental set-up. A carrier signal generated from a local oscillator (LO) together with a two-level data signal is applied to one port of a metadevice. The modulated signal terminated by a 50-Ω load is measured in the second port.

FIG. 5B shows a modulated signal corresponding to a 30 GHz carrier signal and 250 Mb s⁻¹ data-rate, limited by the utilized arbitrary signal generator.

FIG. 5C shows an ultrahigh speed data transmission with a 50-GHz carrier and a sinusoidal signal as the data source, resulting in a 6 Gb s⁻¹ data transmission.

FIG. 5D shows instantaneous power corresponding to the waveform shown in FIG. 5C. The output power at 50 GHz was limited by the VNA.

FIG. 6 shows a FFT of the modulated signal of FIGS. 5A to 5D.

FIG. 7 shows a microscopic manipulation of radiofrequency fields using metastructures.

FIG. 7A to 7I shows an electric field (E_{z}) at the barrier of a metadevice for frequencies between 25 and 65 GHz, showing that the subwavelength field manipulation shapes up and remains for a very wide frequency range. Simulation results indicate that the effect of the metastructure can be modeled by a gigantic k² (k is the wavenumber) with a negative sign (k²<<−k₀², where k₀=ω\sqrt{με}).

FIG. 7J shows E_{z} at the barrier along the middle stripe length for frequencies between 5 GHz and 100 GHz with a step size of 5 GHz.

FIG. 7K shows a maximum of field intensity at the barrier for different frequencies. The field drops very sharply at the beginning, until the frequency of strong interaction at 50 GHz. After that, the field intensity increases smoothly. This low electric field with a quasi-1D shape even after 50 GHz (FIGS. 1G, 1H, 1I), together with the intrinsic confinement of current in the subwavelength TM mode (FIG. 1J) results in a smooth decrease in the resistance, even after the frequency of strong interaction. Therefore, the switch with a frequency of strong interaction at fₛᵢ=50 GHz shows very high performances for frequencies even beyond 2fₛᵢ.

FIGS. 8A to 8F show metastructure design flexibility to operate at terahertz frequencies. The electric field (E_{z}) at the barrier of a metadevice with 2-μm-long 200-nm-wide stripes, excited by a 1-V radiofrequency source. The gap length is 100 nm, the barrier thickness is 10 nm, and the sheet resistance of 2DEG is 300Ω/. The field pattern at the frequency of strong interaction is shown for devices with N number of stripes, where in FIG. 8A N=4, in FIG. 8B N=6, in FIG. 8C N=8, in FIG. 8D N=10, in FIG. 8E N=14. FIG. 8F shows a peak of E_{z} at the barrier at the frequency of strong interaction and without interaction (f=10 GHz). While the low-frequency field intensity is almost constant for different stripe numbers, the intensity at the strong interaction regime drops drastically. This opposes the typical displacement field-frequency relation, as the field intensity should drop at higher frequency. However, the 14-stripe device, exhibiting the lowest interaction frequency, shows the lowest field intensity which is in favor of the device performance (lower potential drop across the device terminals).

FIGS. 9A to 9B show resistance versus frequency for a conventional and a metadevice. Comparison between the ON-state resistance of a 40-μm conventional device and a metadevice with 8 stripes. FIG. 8A—Experiment, FIG. 8B—Simulation. The total resistance of the device drops sharply as it approaches the strong interaction frequency. The resistance stays low after the frequency of strong interaction, due to the wide-band nature of the interaction, as well as the intrinsic confinement of current density at higher frequencies (FIG. 1E).

FIG. 10 shows capacitance versus frequency for a conventional and a metadevice. Depleting the 2DEG vanishes the collective coupling in the metadevice. As a result, the OFF state capacitance of both the metadevice and the conventional device scales linearly with the scaling factor S.

FIG. 11 shows simulated cut-off frequencies. Simulated capacitance (C_{OFF}) and resistance (R_{ON}) of conventional devices (widths: 5 μm, 10 μm, 15 μm, 20 μm, 30 μm, 40 μm) and metadevices (stripe numbers: 2, 4, 6, 8, 10, 12, 14) at 50 GHz. Simulation results indicates the superior performance of metadevices, as well as the enhanced performance with increasing the number of stripes.

FIG. 12A to 12B show radiofrequency characteristics with a dc sweep. FIG. 11A shows a measured channel impedance of a 4-stripe metadevice at 50 GHz. Real part, and imaginary part. At zero bias (V_{b}=0) the device is in the ON state, with a near-zero imaginary part. By applying a dc bias larger than 3.5 V the device turns OFF due to a displacement-field switching resulting in about three orders of magnitude change in the imaginary part of the impedance. The device has two symmetrical schottky contacts, so the bias is polarity independent. Therefore, the second derivative of the channel impedance at zero bias is zero. As a result, the device potentially exhibits a high linearity at zero bias. In addition, the device exhibits a sharp switching that enables data modulation (FIG. 5) and mixing. The change in the capacitance is minor after 6 V bias, but in all cases when it is referred to the OFF state, a 20 V bias has been applied. FIG. 11B shows corresponding transmission (S₂₁) for different bias voltage showing a low insertion loss at V_{b}=0 V, which is almost flat over frequency.

FIGS. 13A to 13C show a metadevice as a mixer. FIG. 13A is a schematic of a two-port metadevice for mixing, where a large-signal local oscillator (LO) and a small signal RF are applied to one port and the second port is terminated by a load. FIG. 13B is a schematic of a three port metadevice including two metastructured pads and a normal gate. FIG. 13C shows mixing of a 50-GHz (RF) with a 15-GHz (LO) signal using a two-port metadevice biased close to the threshold at 3.5 V. The output signal indicates both second harmonic generation as well as mixing.

FIGS. 14A to 14E shows an evaluation of the linearity of metadevices. FIG. 14A shows the experimental set-up. To obtain the input power the inventors measured a through feature that short circuits two ports. FIG. 14B shows input and output radiofrequency powers at 10 GHz, for the fundamental frequency as well as the third harmonic, showing a high-power highly-linear performance.

FIG. 14C shows sample input and output voltage waveforms showing a deformation-less high-amplitude operation. Scattering parameters of (FIG. 14D) the radiofrequency probe (port 2) are shown, and of (FIG. 14E) the cable connecting port 2 to oscilloscope port.

FIGS. 15A and 15B show de-embedding of R_{ON} and C_{OFF}. FIG. 15A shows a measured ON-state resistance of a metadevice, as well as the measured resistance of a short circuit (through) feature which has exactly the same geometrical properties of the main device, however, with the gap filled with metal.

FIG. 15B shows measured OFF-state capacitance of the device, as well as the measured capacitance between signal tips when the radiofrequency probes are in a separation, while keeping the distance as we performed C_{OFF} measurement.

FIG. 16 shows Table 1 comparing terahertz switches realized based on metadevice concept with classic devices.

FIG. 17A shows a simplified structure of a displacement-field nano-switch realized on a high-electron-mobility heterostructure with a few-nanometer thin barrier. FIG. 17B shows a transmission electron microscopy (TEM) image of an ultra-scaled displacement-field nano-switch with a 50-nm gap distance, together with energy-dispersive X-ray (EDX) spectroscopy for Tungsten (metallic pads), Indium, and Gallium. FIG. 17C shows the channel impedance in diodes and field-effect transistors lies in the real axis, while a displacement-field switch relies on the modulation of the imaginary part of the impedance. FIG. 17D shows a measured channel impedance (real and imaginary parts) for a displacement field nano-switch showing three orders of magnitude switching in the imaginary part of the channel impedance. FIG. 17E shows implementation of a three-port displacement-field nano-switch with a back gate realized by a 600-nm-thick epitaxially grown highly doped (1×10¹⁹ cm³) GaN layer. The results show 20 times change in impedance at 50 GHz corresponding to a 26 dB switching. FIG. 18A shows an experimental setup to evaluate signal transmission through metal-2DEG coupling. The SEM image shows a 300-nm-long-gap device. Scale bar is 10 μm. FIG. 18B shows a transmission scattering parameter of a 7.5-nm-thin barrier based on InAlN and a 27-nm-thin barrier based on AlGaN, both providing Rₛₕ˜300Ω/□. With respect to the through feature (short circuit of input and output terminals), the thin-barrier provide a 2.5-times lower insertion loss. FIG. 18C shows a circuit model based on distributed capacitance-resistances indicates a higher performance for ultrathin barrier epitaxies, as the metal-2DEG coupling enhances due to a lower barrier reactance X_{bar}.

FIG. 19A shows ON-state resistance of displacement field nano-switches with straight-gap distances g=220 nm, 320 nm, 420 nm, 520 nm, and 620 nm. The total resistance of 220-nm-long channel devices reaches 200Ω·μm at frequencies above 100 GHz. The inset shows the SEM image of a switch. The scale bar is 300 nm. FIG. 19B shows the extracted effective contact resistance of the devices using TLM at radiofrequencies. Measurements at 30 GHz and 100 GHz show almost identical sheet resistance, however, the contact resistance drops at higher frequencies thanks to a stronger metal-2DEG coupling.

FIGS. 20A to 20D show a comparison of ON and OFF states of devices with (FIG. 20A) straight-gaps and (FIG. 20B) multi finger pads in which the devices consist of 1.2-μm-wide 10-μm-long fingers, with the same gap length g. FIGS. 20C and 20D show normalized R_{ON} and C_{OFF} of straight-gap devices for different gap lengths. 220-nm-long gap devices exhibit R_{ON}=444Ω·μm and C_{OFF}=237 aF·μm⁻¹ at 50 GHz resulting in a 1.5 THz cut-off frequency. FIGS. 20C and 20D also show Normalized R_{ON} and C_{OFF} of microstructured devices with 16 fingers for different gap lengths. 220-nm-long gap devices exhibit R_{ON}=197 2 un and C_{OFF}=130 aF·μm⁻¹ at 50 GHz resulting in a 6.2 THz cut-off frequency. These results indicate a lower resistance and a lower capacitance for multi finger devices.

FIG. 21 shows the channel impedance corresponding to the OFF state capacitance and ON state resistance for the microstructure device shown in the inset (the scale bar is 4 μm). Measurements at 100 GHz shows an 8.1 THz cut-off frequency.

FIG. 22 is a benchmark of multi finger displacement-field nano-switches fabricated on epitaxy A (InAlN/AlN/GaN with a thin barrier) and epitaxy B (AlGaN/GaN with a thick barrier). The devices exhibit a superior performance comparing to traditional electronic devices such as transistors and diodes.

FIGS. 23A to 23C show scattering parameters of a 4-finger displacement-field nano-switch in ON and OFF states, with FIG. 23A showing Transmission (S₂₁), and FIG. 23B showing Reflection (S₁₁). The switch exhibits a low insertion loss<1 dB at 100 GHz with over 10 dB isolation. FIG. 23C shows that the device geometry such as number of fingers can tune the matched frequency band.

FIG. 24A shows an image of an experimental setup in which one port of the switch is excited by carrier and data signal and the second port is terminated by the 50-Ω port of a 70-GHz scope. FIG. 24B is a photograph of the switch connected to radiofrequency 67 GHz GSG probes. FIG. 24C shows 6 Gb s¹ speed data transmission with a 50-GHz carrier. FIG. 24D shows instantaneous power corresponding to the waveform shown in FIG. 24C. FIG. 24E shows a FFT of the modulated signal. FIG. 24F shows high power operation of a switch with a 100-μm effective width. Dashed line (input), solid line (output). The 13.5-dBm output power was the VNA limit. FIG. 24G shows displacement field switches for mixing and second harmonic generation, using a 15 GHz LO and 50 GHz RF signals. FIG. 25 is a schematic showing a non-limiting and exemplary embodiment of the semiconductor device or the electronic metadevice of the present disclosure.

FIGS. 26A and 26B shows is a schematic showing a non-limiting and exemplary embodiment of the semiconductor device or the electronic metadevice of the present disclosure comprising a three-terminal device and including a gate electrode. FIG. 26A shows an exemplary top gate, and FIG. 26B shows an exemplary back-gate.

FIG. 27 shows a table including geometries of metadevices for microwave, mm-wave, and THz operation. Electronic metadevices with different geometries realized on an InAlN/GaN heterostructure. Devices with a shorter stripes exhibit a better performance at higher frequencies.

FIGS. 28A to 28D shows high-frequency characterization of electronic metadevices, where FIG. 28A is a schematic of the experimental setup to characterize electronic metadevices based on complex scattering parameters; FIG. 28B is a photograph of the setup corresponding to 0.75-1.1 THz band;

FIG. 28C shows measured ON-state resistance (R_{ON}) and OFF-state reactance (X_{OFF}) of a terahertz metadevices with 8 stripes (1.7 μm×330 nm) and channel length of 120 nm (inset) versus frequency;

FIG. 28D shows a benchmark of metadevices with mainstream electron devices on a C_{OFF}-R_{ON} plane showing outstandingly high cutoff frequency FOM for electronic metadevices. Dashed lines represent the impedance of a 3.8Ω resistance and a 2.3 fF capacitance. Electronic metadevices can achieve R_{ON} values below 10Ω at very high frequencies, corresponding to insertion losses below 1 dB.

FIGS. 29A to 29G concern a circuit model of electronic metadevices, where a schematic of the cross section of metadevices is shown in FIG. 29A, FIG. 29B shows ON, OFF states; FIG. 29C shows a proposed compact circuit model including four elements R_{ch} (channel resistance) R_{C} (contact resistances), X_{S}=Lω−(Cω)⁻¹ (reactive impedance due to the metal-semiconductor coupling), and C_{P} (capacitance between the interdigital metals); FIG. 29D shows Extracted C_{S} and L_{S} at different voltages (discrete points). The inductance play a negligible role in the OFF-state reactance, and therefore, it can be considered constant (L_{S}=50 pH) for the entire voltage range. The measured capacitance was empirically fitted by

$${C}_{S} ( V ) = 260 {( 1 + \frac{1}{25} ( \vert V \vert / {V}_{th} ) + {( V / {V}_{th} )}^{20} )}^{- 1} + 9.5 fF ,$$

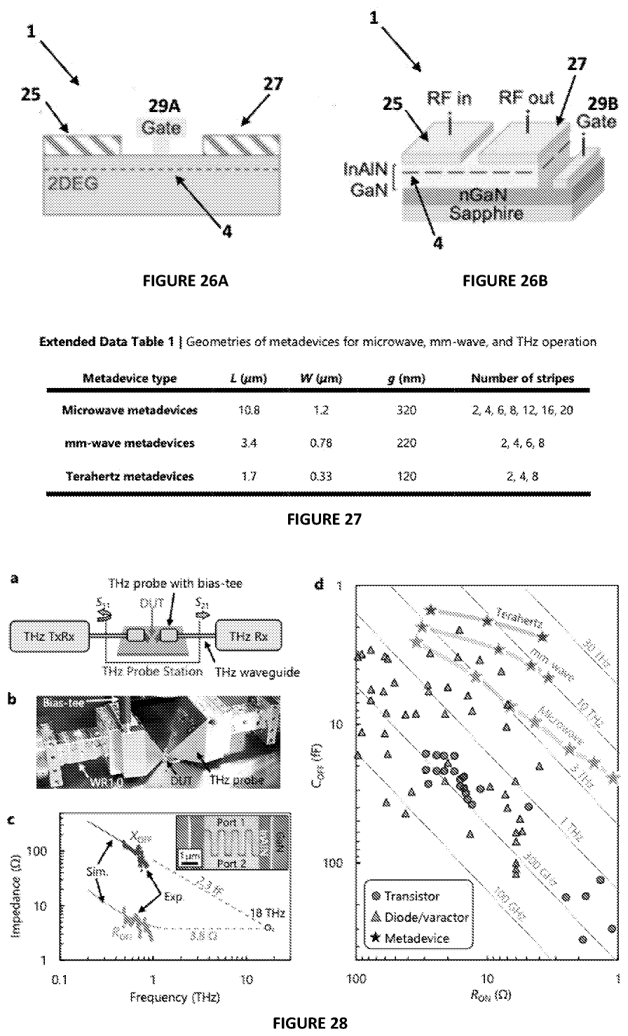

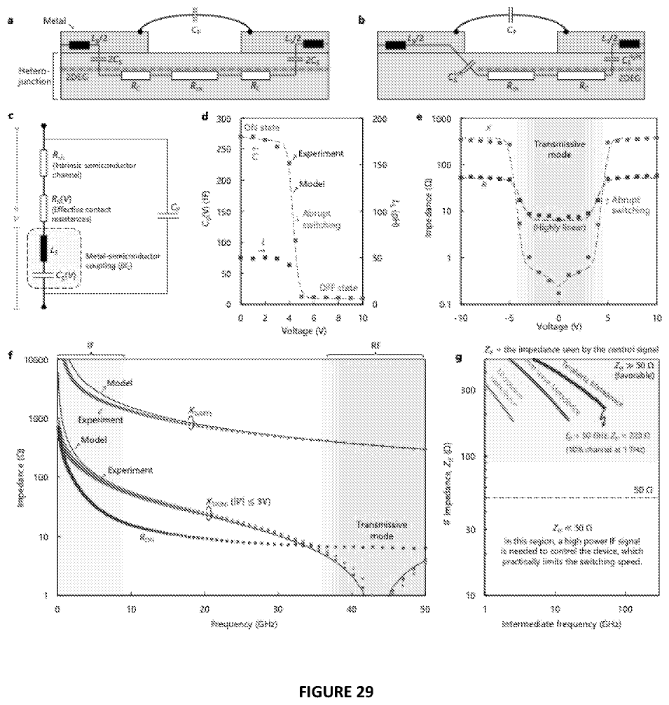

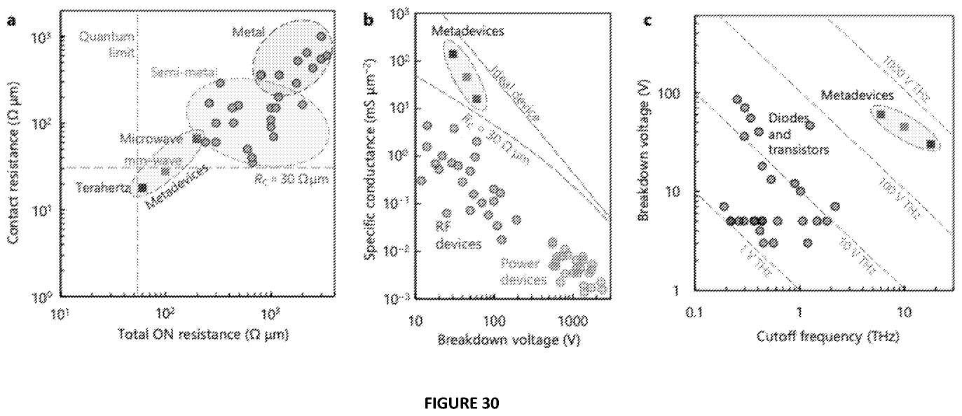

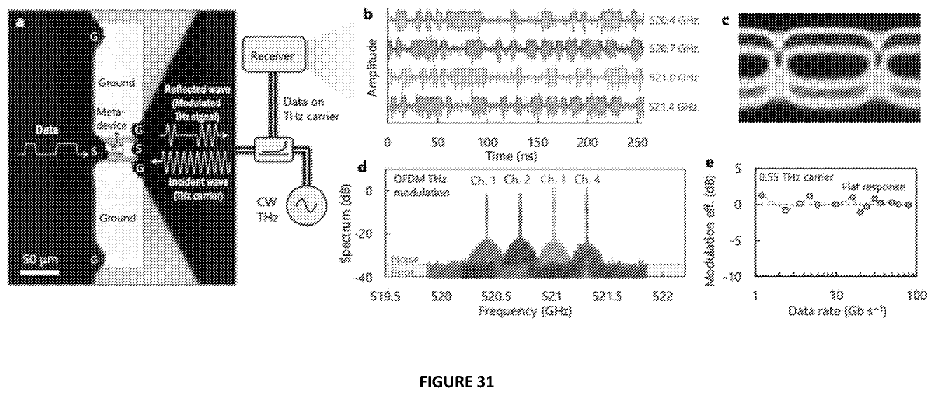

with Vₜₕ=4.3 V (dashed line). FIG. 29E shows measured (discrete points) and modeled (solid lines) impedances at the resonance frequency (ω=ω_{0S}). Red (real part), blue (imaginary part). The total resistance was modeled by R_{ch}+R_{S}=6.5+45(1+(V/Vₜₕ)⁻¹⁰)⁻¹Ω. The device exhibits a very linear ON state followed by an abrupt switching. FIG. 29F shows broad-band measured impedance of the device in ON (|V|≤3 V) and OFF states (V=10 V) (discrete points), showing a very good agreement with the model (solid lines). In a wide range of frequencies around the resonance, the imaginary part of the impedance is very small and negligible compared to R_{ON}, which shows the wide band nature of the transmissive mode. FIG. 29G shows absolute values of the impedance of the 6-stripe microwave metadevice, as well as 4-stripe mm-wave and terahertz metadevices (parameters described in FIG. 27) at intermediate frequencies. Considering data modulation with a 10% bandwidth, the devices show a high impedance for the control (data) signal, while exhibiting a low impedance for the carrier signal.

FIGS. 30A to 30C show electronic metadevices with ultrahigh conductances and breakdown voltages, where FIG. 30A shows normalized contact resistance and total ON-state resistance of metadevices and classic devices with tunneling junctions based on metal and highly-doped semiconductor (semi-metal) contacts, electronic metadevices exhibit ultrahigh conductance values; FIG. 29B shows specific conductance versus breakdown voltage for electronic metadevices and classic radiofrequency and power devices, the performance of metadevices is very close to the ideal limit corresponding to the critical field of GaN (3 MV cm⁻¹) and a sheet resistance of 200Ω/; and FIG. 30C shows breakdown voltage versus f_{CO} for transistors and diodes, as well as electronic metadevices.

FIGS. 31A to 31E show high-performance THz data transmitters using electronic metadevices, where FIG. 31A is an optical microscope image of an electronic metadevice modulator. The data signal, fed into the left port, modulates the incident THz wave injected in the right port. The reflected wave is the data signal on the THz carrier which is received by a coherent receiver. FIG. 31B shows received modulated signals with four different carrier frequencies. The very high ON/OFF ratio shows that metadevice modulators are operational at frequencies much above 0.5 THz. FIG. 31C is an eye diagram of the 520.4 GHz channel indicating an excellent modulation. FIG. 31D shows a spectrum of the received signals. The high-performance modulation results in almost zero cross talk between channels which indicates the potential of metadevice modulators for ultra-dense allocation of channels in massive communication networks. FIG. 31E shows the modulation efficiency (normalized to that obtained at 100 MHz) versus data rate, indicating an efficient modulation of THz signals with very high data rates.

Herein, identical reference numerals are used, where possible, to designate identical elements that are common to the Figures. Also, the images are simplified for illustration purposes and may not be depicted to scale.

### DETAILED DESCRIPTION OF SEVERAL EMBODIMENTS

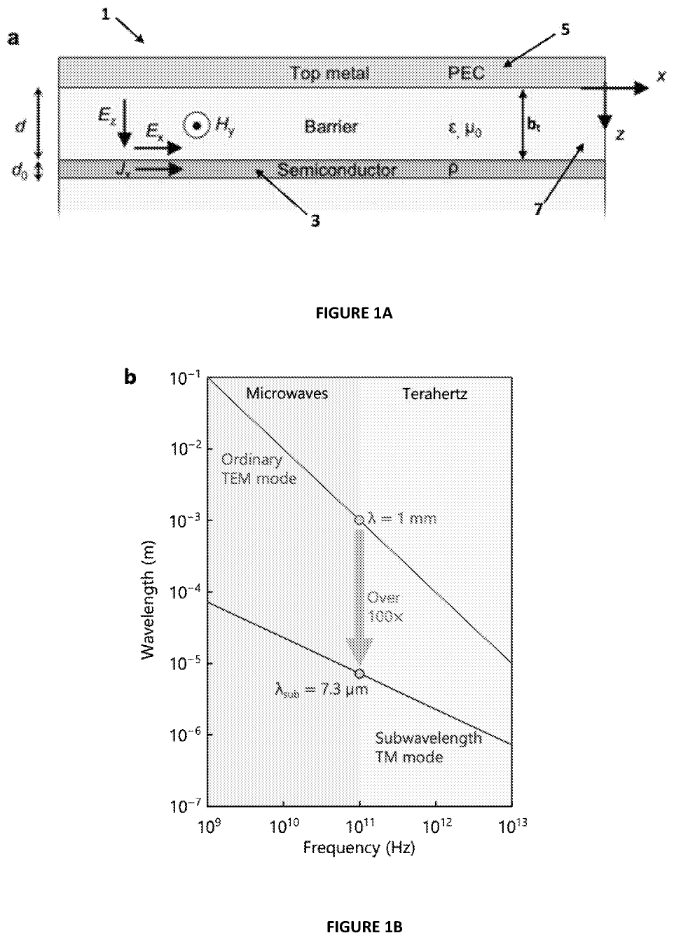

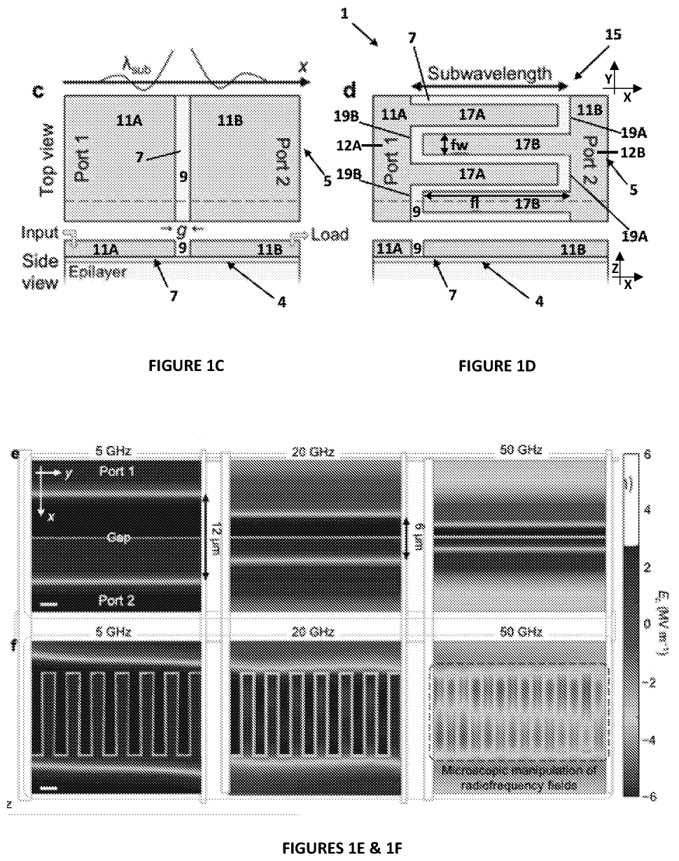

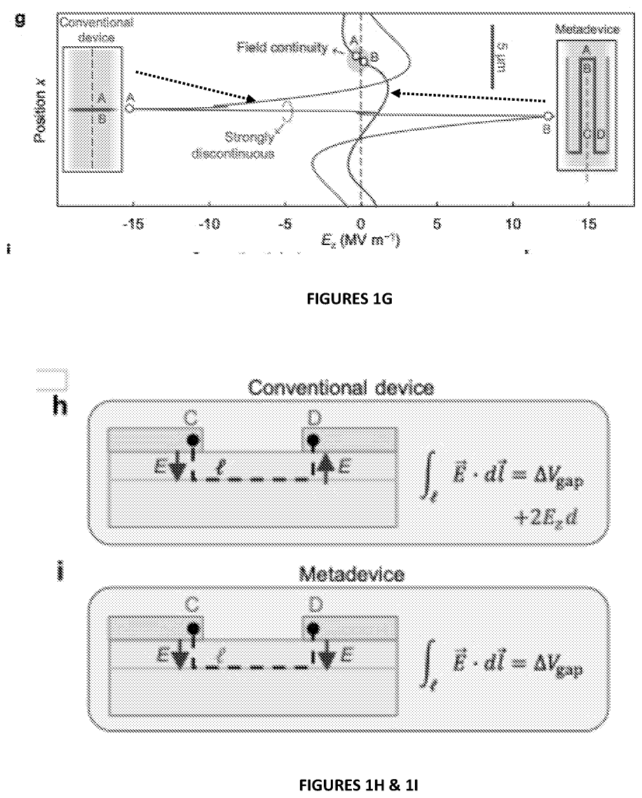

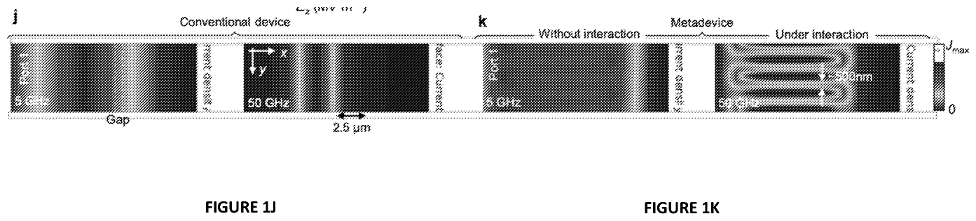

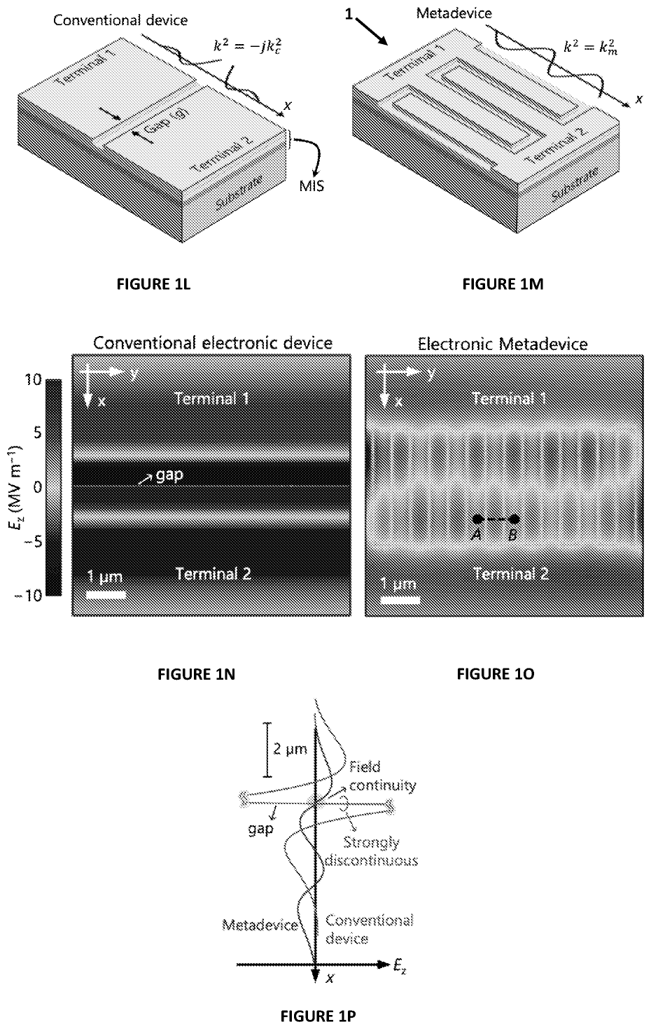

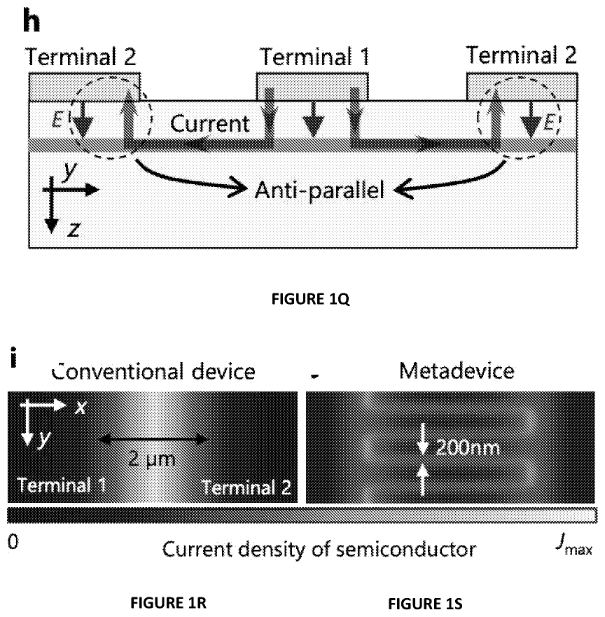

FIGS. 1A and 1D are schematics of an exemplary device 1 of the present disclosure. The device 1 is, for example, a semiconductor device or an electronic metadevice, or an electronic semiconductor metadevice 1.

The device 1 comprises at least one conductive channel 3 configured to provide charge carriers 4, at least one metal (or metallic) layer or material 5 superposed on the at least one conductive channel 3, and at least one barrier layer or material 7 located between the at least one metal layer or material 5 and the at least one conductive channel 3.

The at least one barrier layer or material 7 may, for example, directly contact the at least one metal layer or material 5. The at least one conductive channel 3 (or a constituent material or layer thereof) may, for example, directly contact the at least one barrier layer or material 7.

The barrier layer or material 7 is or defines a current barrier configured to restrict or prevent current flow therethrough during operation of the device 1.

The barrier layer or material 7 is configured to prevent current flowing through the barrier layer or material 7, for example, from the conductive channel 3 to the metal layer or material 5. The barrier layer or material 7 is preferably an electrically insulating or insulator layer or material located between the metal layer or material 5 and the conductive channel 3 and physically separating the metal layer or material 5 and the conductive channel 3.

The barrier layer or material 7 may, for example, comprise or consist of a III-V semiconductor material, or a wideband-gap semiconductor material. For example, FIG. 25 shows an non-limiting example of the barrier layer or material 7 comprising InAlN.

The barrier layer or material 7 has a relatively small thickness, for example, a thickness bₜ, where bₜ<30 nm, or bₜ 15 nm, or bₜ<10 nm, or bₜ 5 nm.

The barrier layer or material 7 is, for example, configured to assure a strong electric field coupling between (i) the metal layer or material 5 and/or the metastructures 15 of the metal layer or material 5 and (ii) the conductive channel (3).

The barrier layer or material 7 can be, for example, configured to polarize an electric field E_{z} in a thickness direction d of the barrier layer or material 7 to assure a strong electric field coupling between the metal layer or material 5 (and/or the metastructures 15 of the metal layer or material 5) and the conductive channel 3.

The metal layer or material 5 and the barrier layer or material 7 are, for example, configured to support transverse magnetic TM modes that interact with the metal layer or material 5 to permit current density confinement. The barrier layer or material 7 can, for example, have a thickness supporting subwavelength transverse magnetic TM modes that interact with the metal layer 5 to permit current density confinement.

The conductive channel 3 can for example be (or comprise or consist of) a semiconductor conductive channel, or can be defined by a semiconductor heterostructure.

Any semiconductor channel 3 can, for example, be used. Examples of such a channel 3 is a channel that is, provides, or assures a two-dimensional electron gas, a two-dimensional hole gas, a n-doped semiconductor, a p-doped semiconductor, or a two-dimensional semiconductor, such as graphene.

The conductive channel 3 can for example be, or comprise or consist of, or be provided by a semiconductor heterostructure, or is defined by a semiconductor heterostructure. The conductive channel 3 can, for example, be defined by a semiconductor heterojunction defined by at least one first semiconductor layer or material 21 and at least one second semiconductor layer or material 23. The first semiconductor layer or material 21 and/or the second semiconductor layer or material 23 may, for example, comprise or consist of a III-V semiconductor material, or a wideband-gap semiconductor material. In the non-limiting exemplary of FIG. 25, the first semiconductor layer or material 21 comprises GaN and the second semiconductor layer or material 23 comprises AlN and a third semiconductor layer or material 7 comprises InAlN, which provide charge carriers 4 as a 2DEG at the interface of the first 21 and second 23 semiconductor layers or materials.

The conductive channel 3 is, for example, configured to provide a two-dimensional electron gas, or a two-dimensional hole gas of charge carriers.

The conductive channel 3 can be, for example, formed via an n-doped semiconductor, or a p-doped semiconductor. The conductive channel 3 can, for example, be formed on or by a two-dimensional semiconductor. The two-dimensional semiconductor may, for example, comprise or consist of graphene, or boron nitride BN, or MoS₂, or WSe, or any other class of 2D semiconductor materials.

The conductive channel 3 can, for example, be defined by a semiconductor material comprising or consisting of a III-V semiconductor material, or a wideband-gap semiconductor material.

The metal layer or material 5 may comprise or consist of at least one or a plurality of metals. For example, FIG. 25 shows an non-limiting example of Au and Ni. The layer or material 5 is, for example, a metallic layer or material.

The device 1 comprises, for example, a metal-insulator-semiconductor (MIS) structure. An insulating barrier 7 of thickness d of the structure separates the outer metal layer or material 5 from the semiconductor material providing the conductive channel 3.

The device 1 may, for example, include a substrate 27 upon which the metal layer or material 5, the barrier layer or material 7 and the conductive channel 3 are superposed. The substrate 27 may, for example, comprise or consist of an insulating material. The substrate 27 may, for example, comprise or consist of sapphire, SiC or Si. These are non-limiting examples and the choice of substrate material will depend on the materials used for the barrier layer or material 7 and the conductive channel 3. The device 1 may, for example, include one or more additional layers or materials, for example, a protective cap layer between the metal layer or material 5 and the barrier layer or material 7.

The metal layer or material 5 is superposed on the barrier layer or material 7 (and the conductive channel 3 or material forming the conductive channel 3) and extends in a plane or in planar manner or in planar directions on the barrier layer or material 7.

The metal layer or material 5 and the barrier layer or material 7, for example, each extend to define a planar layer or planar material, in an X, Y direction as shown, for example, in FIG. 1A. The layers or materials of the device 1 can be superposed and each one extend or define a superposed planar structure.

The metal layer or material 5 includes at least one recess or cavity or gap or slot 9 that extends into and/or through (Z direction) the metal layer or material 5 to define or delimit at least one metamaterial structure or metastructure 15. The at least one recess or cavity 9, for example, extends only into/or through the metal layer or material 5.

The metal layer or material 5 includes the at least one recess or cavity 9 that extends into and/or through the metal layer or material 5 to define or delimit at least one first metal layer portion 11A and at least one second metal layer portion 111B. The first metal layer portion 11A is adjacent to the second metal layer portion (111B).

The first metal layer portion 11A is, for example, a metastructured portion 11A and the second metal layer portion 11B is, for example, a metastructured portion 11B. The metastructure 15 may thus comprise the first metastructured portion 11A and/or the second metastructured portion 11B.

The at least one recess 9 extends through the metal layer or material 5 to define a micro-structured, 30 micro-patterned or micro-textured metal layer 15; or a nano-structured, nano-patterned or nano-textured metal layer 15.

The first and/or second metal layer portions 11A, 11B may be micro-structured, micro-textured or micro-patterned portions 11A; or nano-structured, nano-textured or nano-patterned portions 111B.

The recess 9 may extend through the metal layer or material 5 to define a micro-structured or a nano-structured first metal layer portion 11A comprising a plurality of first metallic extensions or fingers 17A. The recess 9 may extend through the metal layer or material 5 to define a micro-structured or a nano-structured second metal layer portion 11B comprising at least one second metallic extension 17B. Alternatively, the recess 9 may extend through the metal layer or material 5 to define a micro-structured or a nano-structured second metal layer portion 11B comprising a plurality of second metallic extension 17B.

The first metal layer portion 11A includes, for example, a first body or support 12A (FIG. 1D). The second metal layer portion 11B includes, for example, a second body or support 12B.

The first metal layer portion 11A may include at least one or a plurality of micro-structured elements or nanostructured elements 17A extending from the first support 12A of the first metal layer portion 11A. The second metal layer portion 11B may include at least one or a plurality of micro-structured elements or nanostructured elements 17B extending from the first support 12B of the second metal layer portion 11B.

The recess 9 extends, for example, through the metal layer or material 5 to define a micro-structured or a nano-structured first metal layer portion 11A comprising at least one first metallic extension or finger 17A extending away from the first support 12A of the first metal layer portion 11A and towards the second metal layer portion 11B. The recess 9 may also extend, for example, through the metal layer or material 5 to define a micro-structured or a nano-structured second metal layer portion 11B comprising at least one second metallic extension or finger 17B extending away from the second support 12B of the second metal layer portion 11B and towards the first metal layer portion 11A.

The first metallic extension or finger 17A is located adjacent to the second metallic extension or finger 17B.

The recess 9 may extend through the at least one metal layer or material 5 to define a plurality of first metallic extensions or fingers 17A extending away from the first support 12A and towards the second metal layer portion 11B. The recess 9 may alternatively or additionally extend through the at least one metal layer or material 5 to define a plurality of second metallic extensions or fingers 17B extending away from the second support 12B and towards the first metal layer portion 11A. The first metallic extensions or fingers 17A are located adjacent to the second metallic extensions or fingers 17B.

The metastructure 15 includes, for example, the micro-structured, micro-textured or micro-patterned 35 metal layer, or the nano-structured, the nano-textured or the nano-patterned metal layer.

The metal or metallic metastructure 15 includes the elements 17A, 17B that are for example of a sub-wavelength or sub-wavelength dimension, or less than that of the wavelength of an operating electromagnetic radiation of the device 1 to assure or provide specific electronic or electromagnetic properties of the device 1.

The metal or metallic metastructure 15 and device 1 is configured to assure microscopic manipulation of radiofrequency fields by the electrical metastructures which leads to outstanding electronic properties of the device 1. The outstanding electronic properties are obtained thanks to the microscopic manipulation of radiofrequency fields from the collective interaction in the metastructures 15. These outstanding electronic properties are discussed further below in relation to different device 1 operations, such as, an exemplary microwave and terahertz switch operating based on switching of electric-fields confined in the barrier 7 located between the subwavelength metallic metastructure 15 and the high mobility electron sheet of the conductive channel 3.

The device 1 provides an excellent coupling between the metastructure 15 and the semiconducting channel 3. The device 1 includes metastructures 15 applied to electronics, enabling collective and controllable electromagnetic interactions in deep-subwavelength scales within the device 1.

The elements of the metastructure that are metallic extensions or fingers 17A, 17B have a length fl that is subwavelength in length, and are arranged or patterned to form the elements of metastructure 15, and can themselves form metastructures. A length fl extends between (i) a tip or an outermost extremity of the extension or finger 17A, 17B located opposite the metal layer portion 11A, 11B and separated by the recess 9 therefrom and (ii) a departure point of extension from the support 12A, 12B of the metal layer portion 11A, 11B, as shown for example in FIG. 1D.

The elements of the metastructure that are metallic extensions or fingers 17A, 17B may have a width fw that is subwavelength. A width fw extends substantially perpendicularly to the direction of extension of the length fl of the metallic extension or finger 17A, 17B, for example in the Y direction.

A depth or thickness of the metallic extensions or fingers 17A, 17B is defined, for example, by the deposition thickness of the metal layer or material 5, which can also be subwavelength in thickness.

The metallic extensions or fingers 17A, 17B have subwavelength λ_{sub} dimensions at GHz and/or THz frequencies. The metallic extensions or fingers 17A, 17B have a length fl that is subwavelength λ_{sub} at GHz and/or THz frequencies. For example, between 3 GHz and 30 THz, or in terms of wavelength, between λ=10 μm and 10 cm, in air).

The metallic extensions or fingers 17A, 17B have a length fl that is or defines a distance that is subwavelength λ_{sub} at a GHz frequency and/or at a THz frequency. The metallic extension(s) or finger(s) 17A, 17B may define or have, for example, a length fl having a value of 30 μm≥fl≥22 μm, or 20 μm≥fl≥5 μm.

The metallic extensions or fingers 17A, 17B have a width fw that is or defines a distance that is subwavelength λ_{sub} at a GHz frequency and/or at a THz frequency. The metallic extension(s) or finger(s) 17A, 17B may define or have, for example, a width fw having a value of 2000 nm≥fw≥50 nm, or 1500 nm≥fw≥50 nm; or 2000 nm≥fw≥10 nm, or 1500 nm≥fw≥10 nm.

The device 1 may include a number nf of metallic extensions or fingers 17A, 17B, where the number nf has, for example, a value of 50≥nf≥2, or 25≥nf≥2, or 10≥nf≥2.

The recess 9 preferably extends fully into and through the metal layer or material 5 (Z-direction) to the barrier layer or material 7, for example, to expose a surface of the underlying barrier layer or material 7.

The recess 9 extends in a direction towards or to the barrier layer or material 7. The recess 9 also extends in a planar direction (X, Y direction) through the metal layer or material 5. The planer direction being, for example, substantially perpendicular to a direction of superposition of the layer or materials (direction of superposition of the metal layer or material 5, barrier layer or material 7, and conductive channel material(s) or layer(s) 3) of the device 1.

The recess 9 extends in a planar direction through the metal layer or material 5 and defines or delimits the elongated metal elements 17A, 17B of the metal layer or material 5. The recess 9 extends to define or delimit at least the first metallic structure 11A (for example, a first metallic electrode, terminal or port) comprising one or a plurality of the first elongated elements 17A, and at least the second metallic structure 11B (for example, a second metallic electrode, terminal or port) comprising or consisting of one or a plurality of the second elongated elements 17B.

The first metallic structure 11A and the second metallic structure 11B are separated or fully separated by the recess 9, and are physically separated metallic structures. The first metal layer portion 11A is, for example, solely indirectly in physical contact with the second metal layer portion 11B via the barrier layer or material 7.

The first elongated element 17A and the second elongated element 17B are fully separated and are physically separated metallic elements by the recess 9. The recess 9 provides the separation and isolation of the metallic elements. The first elongated element 17A is, for example, solely indirectly in physical contact with the second elongated element 17B via the barrier layer or material 7.

The recess 9 may, for example, contain the surrounding air or an insulating material.

As shown for example in FIG. 1D, the recess 9 extends, for example, through the metal layer 5 to define the metallic extension or finger 17A of the first metal layer portion 11A and at least one depression or trench 19A of the second metal layer portion 111B. The metal extension or finger 17A is received or surrounded by the at least one depression 19A. The recess 9 extends, for example, to define a plurality of metallic extensions or fingers 17A of the first metal layer portion 11A and a plurality of depressions 19A of the second metal layer portion 11B, the metal extensions or fingers 17A being received or surrounded by the depressions 19A.

The recess 9 extends, for example, through the metal layer 5 to define the at least one metallic extension or finger 17B of the at least one second metal layer portion 11B and at least one depression or trench 19B of the first metal layer portion 11A. The metal extension or finger 17B is received or surrounded by the depression 19B. The recess 9 extends, for example, to define a plurality of metallic extensions or fingers 17B of the second metal layer portion 11B and a plurality of depressions 19B of the first metal layer portion 11A. The metal extensions or fingers 17A are received or surrounded by the depressions 19B.

The first metal layer portion 11A and the second metal layer portion 11B comprise a plurality of interleaving metallic extensions or fingers 17A, 17B separated by the recess 9. The recess 9 extends through the metal layer 5, for example, in a serpentine manner to define a plurality of interleaving metallic extensions or fingers 17A, 17B separated by the recess 9, or each metallic extension or finger 17A, 17B being separated by the recess 9.

The metallic extensions or fingers 17A, 17B of the first metal layer portion 11A and/or the second metal portion 11B may extend, for example, substantially parallel to each other. The metallic extensions or fingers 17A, 17B may, for example, have or define identical planar profiles or shapes. Alternatively, the metallic extensions or fingers 17A, 17B may, for example, have or define non-identical planar profiles or shapes.

The metallic extension(s) or finger(s) 17A, 17B of the first metal layer portion 11A and/or the second metal portion 11B may, for example, have or define a rectangular profile or shape, or an elongated triangular profile or shape, or an angular profile or shape, or a mix of any two or more of these profiles or shapes.

The recess 9 defines a separation gap distance g between the first metal layer portion 11A and the second metal layer portion 111B. The recess 9 also defines a separation gap distance g between the metallic extensions or fingers 17A, 17B of the first metal layer portion 11A and the second metal portion 11B. The separation gap distance g can be, for example, substantially the same along the extension path of the recess 9 across the metal layer or material 5 as the recess 9 extends through the metal layer 5 to define the first metal layer portion 11A and the second metal layer portion 11B and the metallic extensions or fingers 17A, 17B thereof.

The separation gap distance g may have, for example, a value of 1500 nm≥g≥20 nm, or 1000 nm≥g≥20 nm, or 600 nm≥g≥20 nm, or 600 nm≥g≥1 nm. A depth of the recess 9 may, for example, correspond to that of the metal layer or material 5.

The device 1 may include at least one or a plurality of input ports 25 (see for example, FIGS. 26A and 26B), and at least one or a plurality of output ports 27.

The plurality of input ports 25 can, for example, be configured to apply multiple voltages to the device 1 to control a signal transmission between input 25 and output ports 27. The device 1 can for example include at least one gate electrode 29A, 29B. The gate electrode 29A, 29B can, for example, be a back-gate 29B, or can be a top gate 29A located between the device input and output ports 25, 27.

The device 1 can, for example, be a three-terminal device comprising a first port 25 and a second port 27, and a gate 29A, 29B.

The first metal layer portion 11A may, for example, define or include the at least one first device port 25 and the second metal layer portion 11B may, for example, define or include the at least one second device port 27.

The device 1 may, for example, include at least one gate electrode 29A, 29B. The gate electrode can be, for example, a back-gate 29B, or can be a top gate 29A located between the first and second device ports 25, 27.

The device 1 can be (or can be operated as) for example a switch, or a displacement field nano-switch, or a tera-hertz nano-switch, or a data transmission device, or an imaging device or a sensing and biomedicine device, or a frequency mixing device or an amplifier.

A switch, or a displacement field nano-switch, or a tera-hertz nano-switch, or a data transmission device, or an imaging device or a sensing and biomedicine device, or a frequency mixing device or an amplifier may include the device 1.

The device 1 of the present disclosure can be fabricated using deposition methods known to the skilled person, such as, molecular beam epitaxy or chemical vapor deposition (for example, metalorganic chemical vapor deposition). Metal films can be deposited using deposition methods known to the skilled person, such as, evaporation or sputtering. Patterning of the device 1, for example the metal layer 5, can be carried out using lithography (for example, electron lithography), dry-etching or wet-etching and lift off.

Further details of exemplary devices 1 of the present disclosure are now presented as well as explanations by the Inventors of device behavior and characteristics.

While particular exemplary materials are disclosed in relation to specific exemplary embodiments, the innovation of the present disclosure is generally applicable to any semiconductors platform, such as III-V, complementary metal-oxide-semiconductor (CMOS), wideband-gap and 2D materials, to explore the full capability of these materials.

The inventors present herein this innovation of the present disclosure by demonstrating microwave and terahertz switches on thin metal-insulator-semiconductor (MIS) structure which supports subwavelength transverse magnetic (TM) modes that collectively interact with a metallic texture 15. This interaction enables the manipulation of electric fields at deep-subwavelength scales and confinement of the current density in a nano-gap between the device terminals. Radiofrequency switches with a critical dimension of 200 nm realized based on the metadevice of the present disclosure exhibited cut-off frequencies beyond 8 THz, breakdown voltage over 50 V. This device 1 of the present disclosure relies on a simple fabrication process revealing its potential to be easily integrated in future high-speed integrated circuits.

FIG. 1A shows a MIS structure, in which the top metal is considered as a perfect electric conductor (PEC) and the semiconductor layer with thickness d₀ is modeled by a resistivity ρ. The wave propagation is assumed to be along the x axis, and the structure is symmetric along the y direction, so the electric fields and current densities have no components along the y axis. It is also assumed that the semiconductor layer is thin enough to ensure a uniform current density (Jₓ) along z direction within the layer. Below the PEC layer there is a dielectric with a permittivity of ε, and the region above is filled by air. Solving the Maxwell's equations for this structure results in

$$\frac{{\partial }^{2}}{{\partial }^{2} x} {E}_{z} - \frac{ρ}{d} \frac{\partial }{\partial x} {J}_{x} + {ξ}^{2} {E}_{z} = 0 , \qquad Eqn . ( l )$$

which for the case of ρ→0 simplifies to an ordinary Helmoltz equation with a TEM solution (see below for more detail). For a non-zero ρ, however, small values of d can make the second term of Eq. (1) dominant. In this case, considering the current continuity in the semiconductor results in:

$$\frac{{\partial }^{2}}{{\partial }^{2} x} {E}_{z} = j \frac{ωε {R}_{sh}}{d} {E}_{z} , \qquad Eqn . ( 2 )$$

where ω is the angular frequency, Rₛₕ=ρ/d₀ is the sheet resistance of the semiconductor. Equation (2) corresponds to a dissipative TM mode with a subwavelength oscillatory nature with wavelength λ_{sub} (FIG. 1B)

$${λ}_{sub} = 2 π \sqrt{\frac{2 d}{ωε {R}_{sh}}} \qquad Eqn . ( 3 )$$

As illustrated in FIG. 1C, by forming a discontinuity on the top metal, exciting the structure from one side and terminating the other side by a resistive matched load, the excited TM mode confines the electric fields close to the gap. In this case, a microwave or a terahertz wave can be confined in one micrometer or below (micrometer or nanometer scale) (FIG. 1B), which is much shorter than the wavelength. In accordance with the innovation of the present disclosure, the inventors show that metallic textures with narrow stripes (FIG. 1D) can collectively interact with this TM mode and enable a microscopic manipulation of radiofrequency fields which offers outstanding electrical properties. When the simple straight gap between two sides of the PEC is replaced by an array of narrow stripes with a length comparable to λ_{sub}, this metallic texture can interact with the subwavelength mode and manipulate radiofrequency fields over the device layout, resulting in exceptional electronic properties in a device form factor. This is the electronic metadevice approach according to the present disclosure.

FIG. 1E shows the simulated E_{z} at the 10-nm-thin barrier between the PEC and a 10-nm-thin semiconductor channel with a sheet resistance of 300Ω/. The electric field is highly polarized in the z direction at the thin barrier, which results in a strong coupling between the top metal and the semiconducting channel. The results also show micrometer-range oscillations from two sides of the 500-nm-long gap. The oscillation wavelength decreases at higher frequencies, as described in Eq. (3).

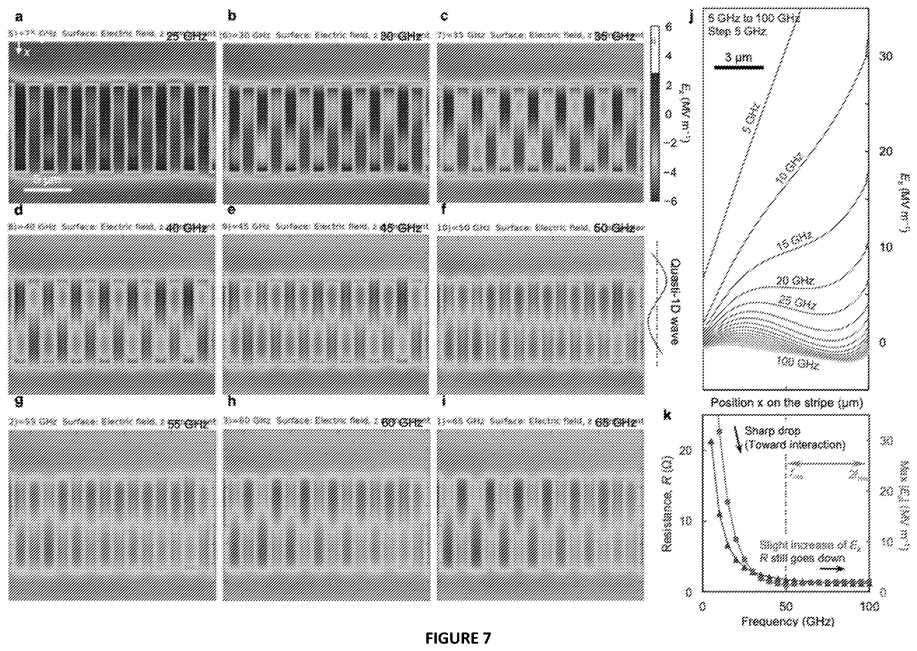

For a metadevice 1 with stripe 17A, 17B width of 1 μm and stripe length of 10 μm, the field pattern at 5 GHz (FIG. 1F, left) is similar to that of the straight gap device (FIG. 1E, left): E_{z} goes to zero in both sides of the gap, with an approximate distance of 12 μm. Increasing the frequency leads to shorter wavelengths which can interact with the stripes. At 20 GHz, two nulls of E_{z} in the case of the straight-gap device are 6 μm apart (FIG. 1E, middle) which is shorter than the stripe length of the metastructure 15. At this frequency, the field pattern in the metastructure 15 becomes different from that in the straight-gap device, as the nulls of electric field stay at the end of stripes and a change in the field pattern inside the stripes appears (FIG. 1F, middle). At 50 GHz, the TM mode exhibits a pronounced interaction with the metastructure 15, enabling a deep-subwavelength manipulation of radiofrequency fields along the propagation direction (FIG. 1F, right). FIG. 7 illustrates the electric field pattern at the barrier 7, for frequencies between 25 GHz to 65 GHz, showing the wide-band nature of the interaction.

FIG. 1F indicates that radiofrequency fields are microscopically manipulated at 50 GHz: E_{z} at the barrier of adjacent stripes 17A, 17B have the same direction, even though they are connected to two different ports 11A, 11B. In addition, the electric field is considerably reduced in the metastructure and goes to zero at the end of the stripes 17A, 17B. This behavior leads to an excellent coupling between two metastructured ports 11A, 111B, as explained in the following. As presented in FIG. 1G, E_{z} has a strong discontinuity in the gap in the case of the straight-gap (conventional) device. Such huge electric fields in opposite directions result in a large ∫_{A}^{B}E·dl, which is translated into a large potential drop between two ports, hindering an efficient signal transmission through the device. The metadevice 1, however, exhibits an E_{z} that crosses zero at the gap, thus the semiconductor under the metallic pad has the same potential of the top metal at the stripe ends. The subwavelength manipulation of electric fields in metadevices 1 also provides an excellent property of signal transmission between the two sides of the stripes 17A, 17B. FIGS. 1H and 1I compare the electric field at the barrier 7 for a conventional device and a metadevice 1, respectively. Considering the case without manipulation (FIG. 1F, left and middle), the E_{z} under two adjacent stripes 17A, 17B has opposite directions resulting in a large vectorial integration of electric field between the metal 5 and the electron channel 3 (FIG. 1H). Thanks to the microscopic manipulation of radiofrequency fields from the collective interaction in the metastructures 1, both electric fields have the same direction, while one stripe 17A, 17B injects current to the other 17A, 17B. In this case, the only term playing a role in ∫_{C}^{D}E·dl is the potential drop in the gap. This provides an excellent coupling between the top metastructure 15 and the semiconducting channel 3.

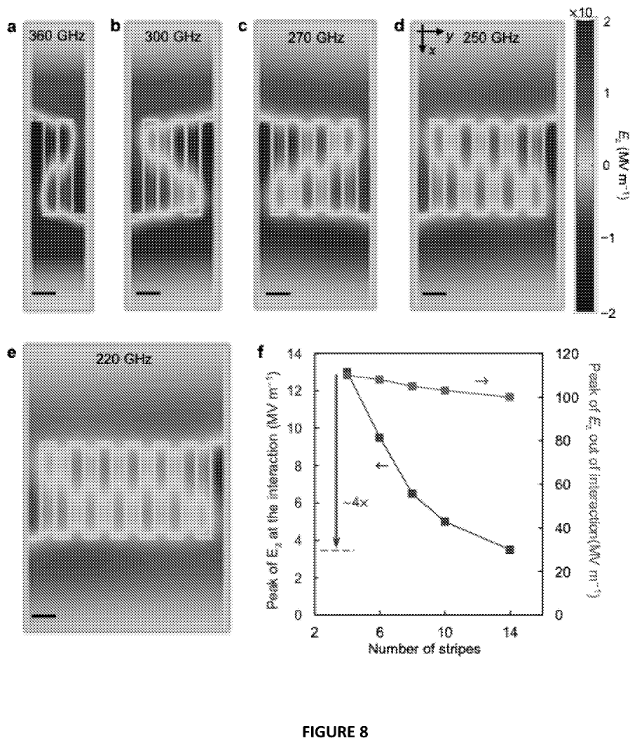

The outcome of this effect can be clearly seen in the current density of the semiconductor layer. As shown in FIG. 1J, for the conventional device, the current is confined in ˜λ_{sub} in both sides of the gap. The current becomes more confined at higher frequencies (λ_{sub} ∝f^{1/2}), however, considering the case of 50 GHz, it still spreads considerably outside the gap. For the metadevice 1 (FIG. 1K), at 5 GHz, the current is largely distributed on the semiconductor layer. At 50 GHz, however, an extremely high current confinement is seen, just close to the 500-nm long gap thanks to the microscopic manipulation of radiofrequency fields. This result predicts an excellent conductance for the metadevice 1, as the current density is only present in the channel. It should be noted that the wavelength of TM mode is inversely proportional to the square root of frequency, so the field manipulation and its outstanding properties can be seen in a wide frequency band (FIG. 7K). In addition, the metallic metastructure 15 can be designed to tune the interaction frequency in the THz range (FIG. 8).

FIG. 1O presents the simulated E_{z} (real part) at the 8-nm-thin barrier of a metadevice 1 (FIG. 1M) with stripe width of 0.4 μm and stripe length of 3.4 μm, showing a very different pattern compared to the straight-gap device (FIG. 1L). Such sub-wavelength manipulation of the electric field pattern can significantly change the electronic properties of the device, and in this case, results in an outstanding signal transmission from terminal 1 to terminal 2.

As presented in FIG. 1P, E_{z} for the straight-gap device has a strong discontinuity close to the gap, which results in a large potential drop across the terminals, hindering an efficient signal transmission. The metadevice 1, however, exhibits an E_{z} that becomes almost zero at the end of the stripes 17A, 17B, resulting an ideal metal-semiconductor coupling. The subwavelength electric field manipulation also provides an excellent property of signal transmission between the two sides of the stripes 17A, 17B, as both electric fields have the same direction, while one stripe injects current to the other (FIG. 1Q). In addition to the same polarities of E_{z} in two adjacent stripes 17A, 17B, its magnitude is also notably reduced compared to the case of straight-gap device. In this case, the effective potential differences at the barrier, at the two sides of the gap cancel each other out and result in an excellent metal-semiconductor coupling. The outcome of such radiofrequency field manipulation can be seen in the current density of the semiconductor layer. As shown in FIGS. 1R and 1S, for the straight-gap device, the current is only confined in ˜λ_{sub} in both sides of the gap. The metadevice 1 exhibits notably more confinement of the current density leading to considerably lower losses, which leads to an extraordinarily high transmission for the metadevice 1.

By applying an electrostatic voltage to one of the terminals, the semiconductor under one terminal is depleted, which completely eliminates the transmissive mode, thus turning off the device. Alternatively, the sub-wavelength mode can be also controlled by a gate electrode. In the OFF state, the device does not show any electric field manipulation, nor current confinement.

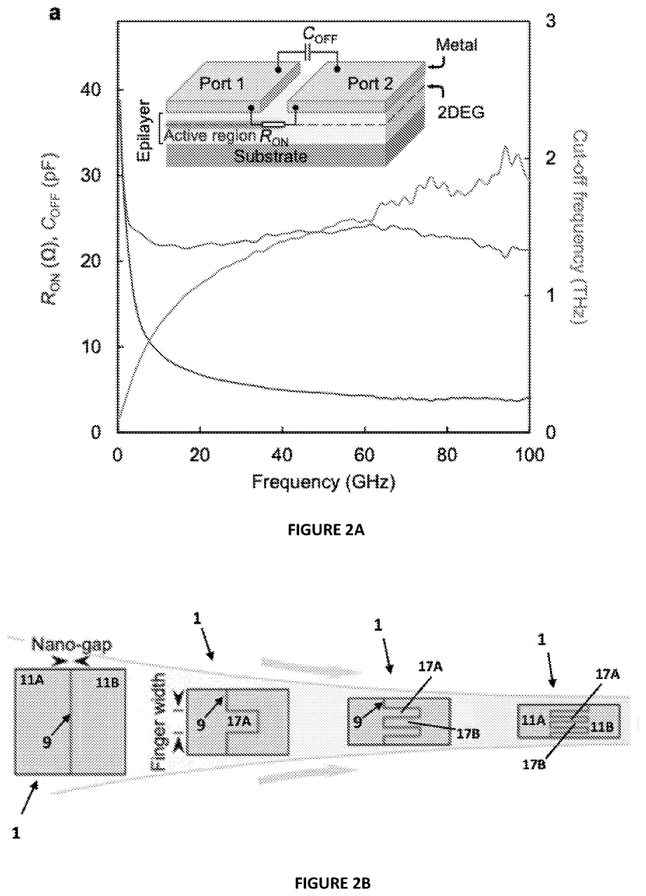

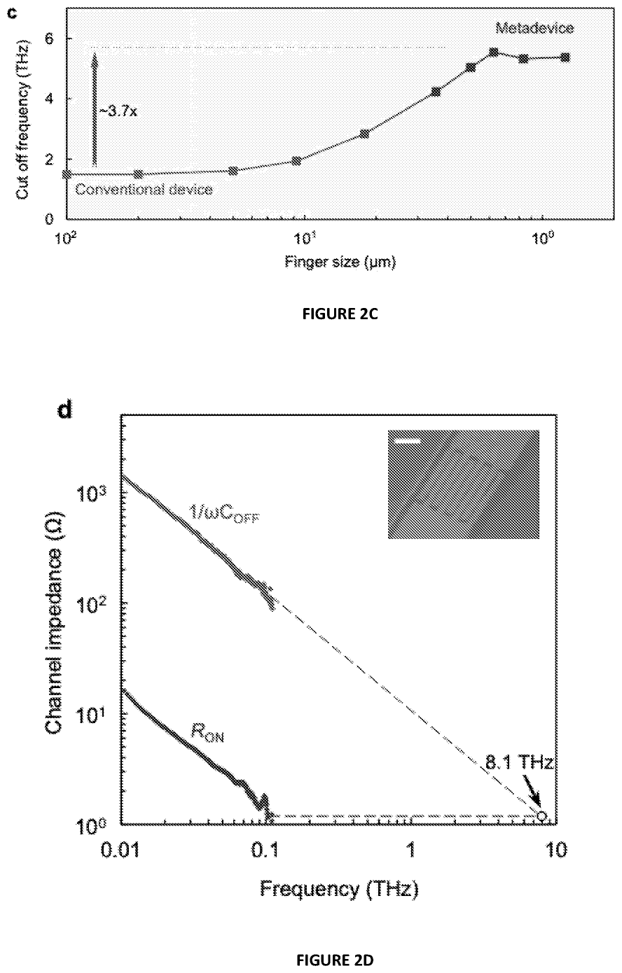

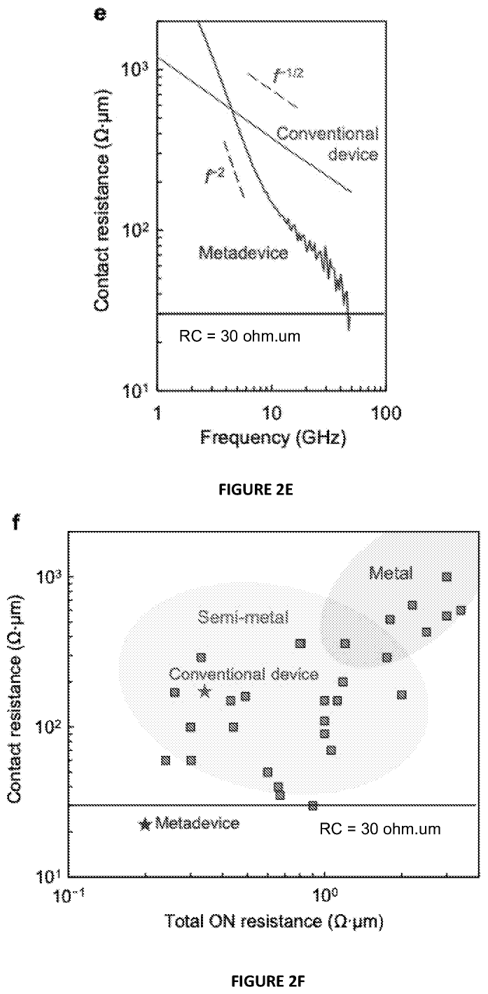

FIG. 2A (inset) illustrates a schematic of a conventional metal-semiconductor-metal (MSM) device on a high-electron-mobility platform with a thin barrier. The device is normally-ON and a radiofrequency signal applied to one of the ports is coupled to a floating two-dimensional electron gas (2DEG) through the subwavelength TM mode, and transmitted to the second port. Notice that such transmission does not rely on ohmic contact between the metal and the channel. The device is turned off by applying a bias larger than the threshold voltage to one of the ports, which depletes the 2DEG and eliminates the coupling. The inventors fabricated devices on an InAlN/GaN epilayer with a 7.5-nm-thin barrier (see later for further details). FIG. 2A shows the measured ON-state resistance and OFF-state capacitance of a 320-nm-long 100-μm-wide gap device, as well as the extracted cut-off frequency. The ON-state resistance drops with respect to the frequency, indicating a stronger coupling at higher frequencies. Measurements at 100 GHz show an R_{ON}=380Ω μm and a cut-off frequency (f_{c}=(2πR_{ON}C_{OFF})⁻¹) of 2 THz. These values are comparable with those obtained by high speed schottky barrier diodes [6] and MSM varactors [23].

Metadevices 1 can be formed by structuring the metallic pads into narrow, subwavelength stripes 17A, 17B, while keeping the gap length fixed at 320 nm. The number of stripes 17,17B was selected such that the device 1 maintains an effective width of ˜120 μm. FIG. 2B illustrates the transition from a conventional MSM switch with a straight gap, towards a metadevice 1 of the present disclosure, in which the stripe width was decreased down to 800 nm. FIG. 2C indicates a notable increase of 3.7 times in the cut-off frequency for metadevices 1 with stripe widths below 1.6 μm. As shown in FIG. 2D, measurements up to 100 GHz indicate a cut-off frequency of 8.1 THz for a metadevice 1.2-μm-wide stripes 17A, 17B (shown in the inset).

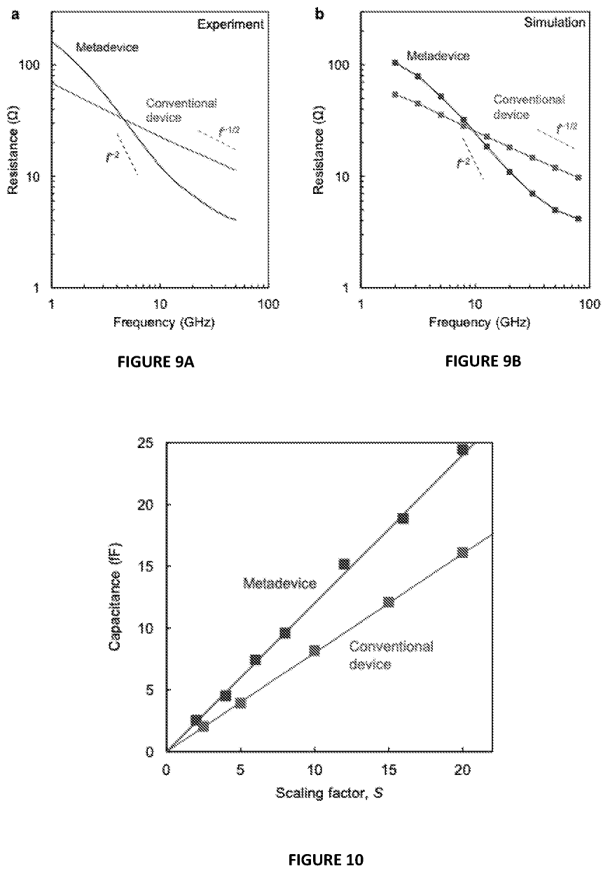

The huge increase of the cut-off frequency for metadevices 1 is mainly due to their higher conductance, thanks to the excellent metal-channel coupling as indicated by the simulations (FIG. 1K, right). The inventors fabricated conventional MSM switches and metadevices 1 with different gap distances 220 nm to 620 nm, and extracted their effective contact resistance by a transmission line measurement (TLM) at high frequencies. As shown in FIG. 2E, the contact resistance of the conventional MSM device drops inversely proportional to the square root of frequency. This is in agreement with the theory presented for the TM mode resulting in a wavelength λ_{sub} as described in Eq.(3): shorter λ_{sub} results in a more confined current density close to the gap and so in a lower R_{C}. The contact resistance of the metadevice 1 is higher than that of conventional devices at low frequencies, which shows agreement with the simulation results presented in FIG. 1J and FIG. 1K, at 5 GHz: the conventional device shows a better current confinement. At higher frequencies, however, the metadevice 1 exhibits a very abrupt decrease in the contact resistance (∝f²), which goes an order of magnitude below that of the conventional device. Such an abrupt drop is also seen in the total resistance of the device (FIG. 9).

Thanks to the collective interaction, the metadevice 1 achieves a contact resistance below 30Ω μm. The total ON-resistance of the metadevice 1 can be notably below 200Ω m which is the lowest resistance ever reported for a III-V semiconductor device. FIG. 2F benchmarks the contact resistance and ON resistance of semiconductor devices, indicating the excellent performance of metadevices 1.

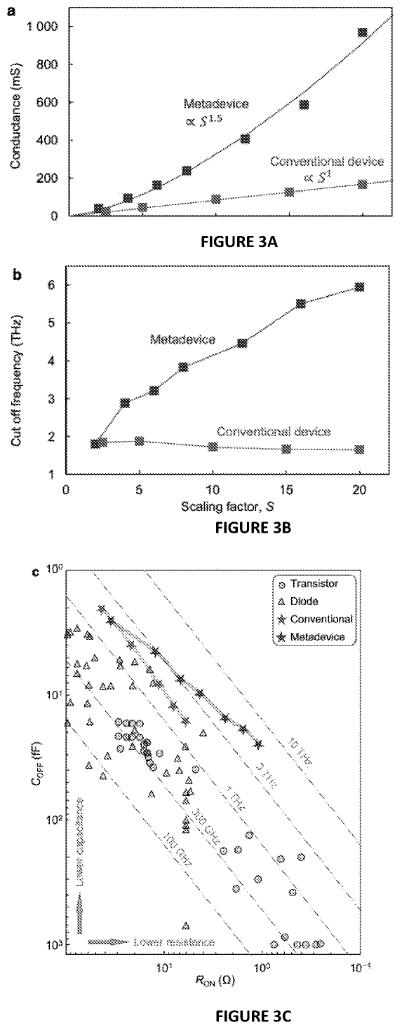

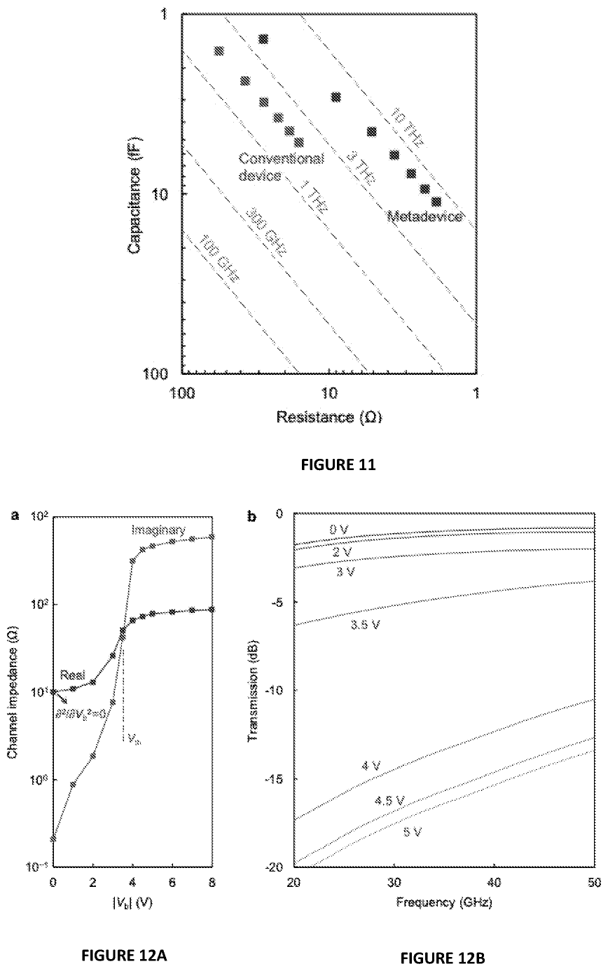

Both measurements and simulation results indicate that the narrow-stripes 17A, 17B in metadevices 1 collectively respond to the TM mode. The conductance of the device grows super-linearly with respect to the number of stripes 17A,17B (scaling factor, S). FIG. 3A shows that G∝S^{1.5} for the metadevice 1, while the conventional device shows the ordinary linear relation. This collective response results in an extraordinary conductance which leads to a high cut-off frequency (FIG. 3B). However scaling conventional devices leads to almost constant cut-off frequencies, as the lower resistance is counterbalanced by the larger off state capacitance. The OFF state capacitance for both conventional devices and metadevices scales linearly with S (FIG. 10). FIG. 3C benchmarks the C_{OFF} and R_{ON} of conventional devices and metadevices with state-of-the-art diodes and transistors. While scaling the conventional MSM switch reduces R_{ON} and increases C_{OFF} at the same rate, so that the cut-off frequency remains constant, the metadevice 1 breaks this trade off by significantly reducing the resistance due to the collective effect of the metastructures 15, which outbalances the increase in C_{OFF}. Simulation results also indicate a super-linear conductance for metadevices 1 leading to higher cut-off frequencies for larger number of stripes 17A, 17B (FIG. 11). The collective response can also be seen in the electric fields confined at the barrier, in which the field intensity sharply drops with increasing the number of stripes (FIG. 8F).

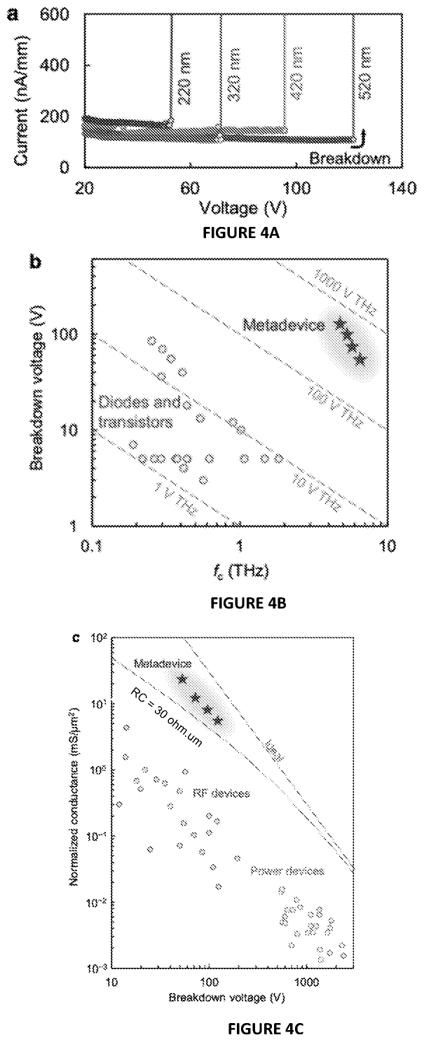

The metadevices 1 not only exhibit extremely high performance at high frequencies, but also provide a very high breakdown voltage, which enables a robust performance and an excellent prospect to operate at large powers. Conventional terahertz switches break at only a few volts [31], while metadevices 1 with very high cut-off frequency show large breakdown voltages over 50 V. FIG. 4A presents the breakdown test of the terahertz switches realized based on the metadevice approach of the present disclosure with different gap distances, showing a low leakage current below 200 nA mm⁻¹, and a very high breakdown voltage, from 50 V for 220-nm-long gaps up to 125 V for 520 nm-long gaps, corresponding to a high average critical electric field of 2.4 MV cm⁻¹. FIG. 4B shows the breakdown voltage versus cut-off frequency for state-of-the-art diodes and transistors, as well as for the metadevices 1. The results reveal that the metadevices 1 considerably outperform the best performance achieved by mainstream electron devices, with a cut-off frequency-breakdown voltage product exceeding the highest reported values in the literature by more than an order of magnitude.

Carrier density and electron mobility together with the critical electric field impose a fundamental trade-off between conductance and breakdown voltage in semiconductor devices. In a lateral device, this trade-off is imposed by the sheet resistance, contact resistance, and the critical electric field. Among radiofrequency devices, the relatively high contact resistances compared to the channel resistance, together with the small-scale features that lead to high electric field peaks, seriously limit their performance, far away from the material limits. However, metadevices 1 exhibiting extremely high conduction with relatively large feature sizes can strongly improve the state-of-the-art.

FIG. 4C shows the normalized conductance versus breakdown voltage for radiofrequency and power devices. The ideal line assumes a zero contact resistance, while the other line indicates the maximum conduction considering with the state-of-the-art contact resistance of RC=30 ohm·um, which is more restrictive for radiofrequency devices. The metadevices 1, being much better than the best conventional devices in the literature, enabling the device performance to approach the ideal device limit determined by the semiconductor material.

Electronic metadevices 1 also provide an excellent dynamic performance and show an ultrafast switching between ON and OFF states, which enables an ultrahigh-speed data transmission. This is an important advantage of terahertz switches realized by metadevice concept with respect to high-cut off frequency switches such as those based on micro-electro-mechanical systems (MEMS) [22], phase-change materials [24], and 2D memristors [25, 26]. For instance, the switching frequency of MEMS and phase-change switches is limited by the speed of mechanical movements [24] and thermodynamics in rearranging the crystallographic structure, respectively. Thus it is not feasible to use these technologies for over gigahertz switching. Memristors can show a higher switching frequency, however, they generally rely on creating filaments with high current densities that causes device-to-device and cycle-to-cycle variability [28], large voltage swing to cover positive and negative turn ON and OFF threshold voltages [29], and limited lifetime [30], which are major challenges for their future use.

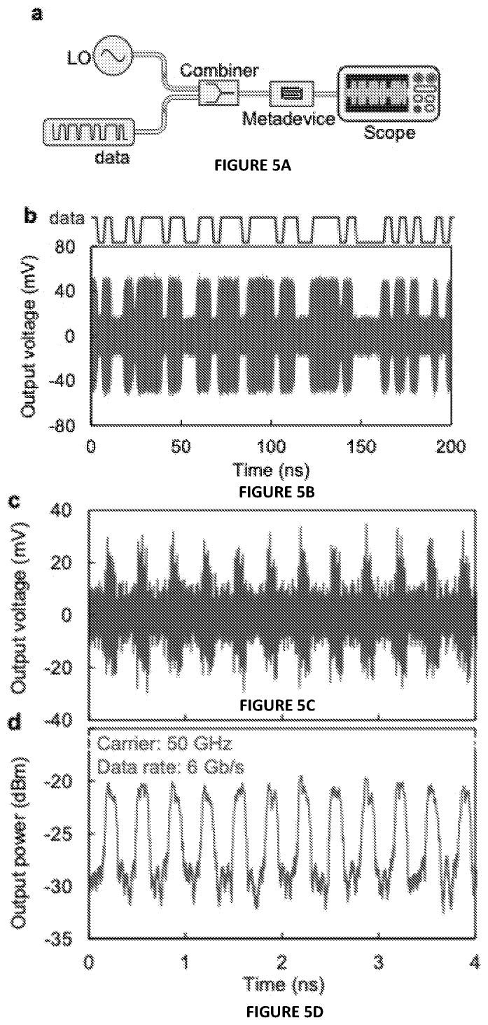

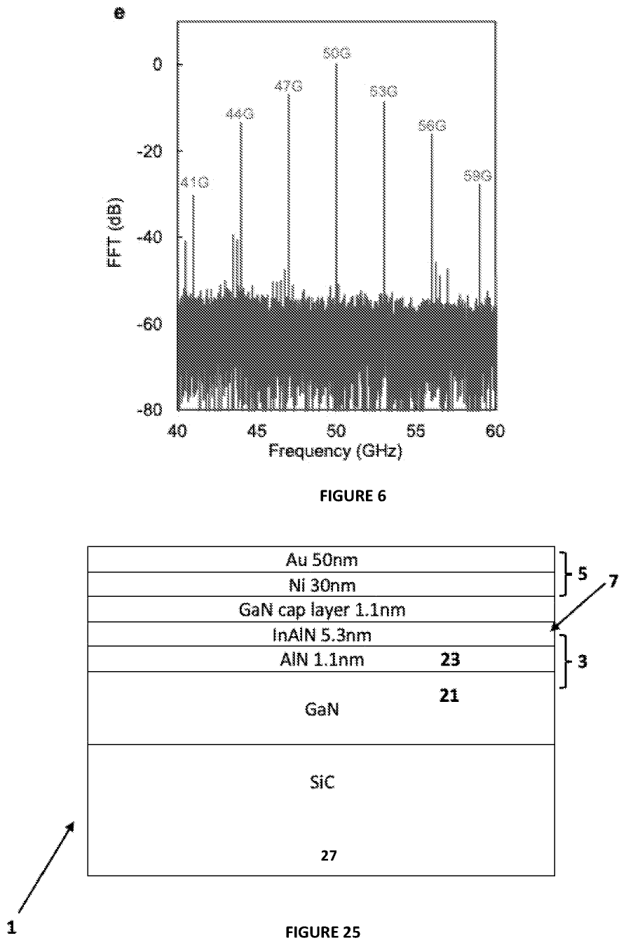

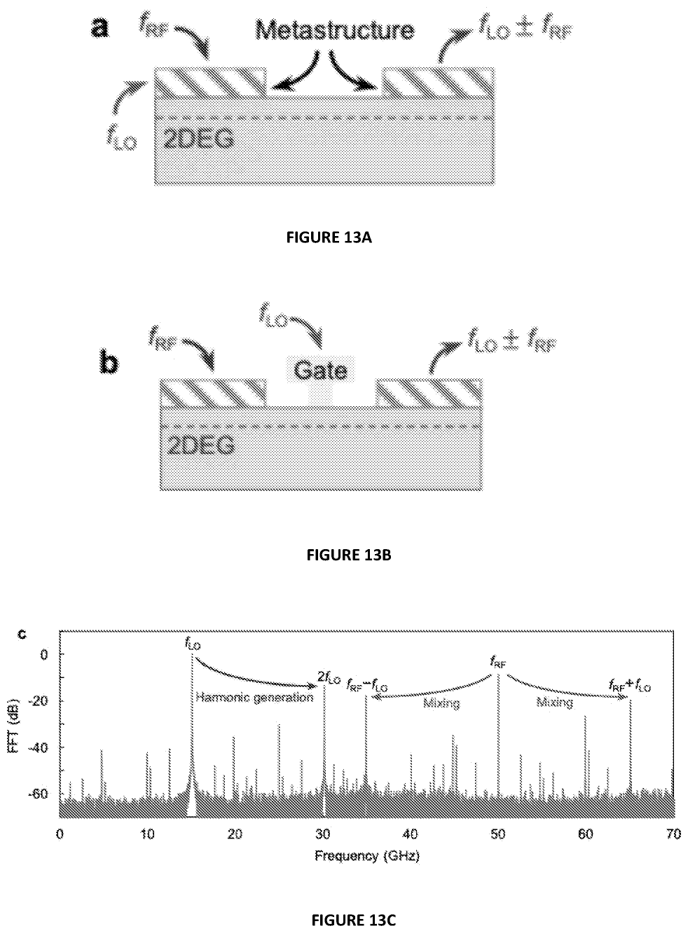

FIG. 5A shows the experimental setup to demonstrate the ultrafast dynamic behavior of terahertz switches realized based on the metadevice 1 approach of the present disclosure. A local oscillator (LO) generates a carrier signal, which is combined to a large-signal base-band data signal, and then applied to one port of a metadevice 1. The switch was biased close to the threshold voltage, at 3.5 V (FIG. 12). The second terminal was terminated by a 504 port of a 70-GHz oscilloscope, to measure the modulated signal. In the first experiment, an arbitrary function generator was used as the source of a data pattern which was modulated using a metadevice 1, with a 30-GHz carrier (FIG. 5B). A data-rate of 250 Mb s⁻¹, limited by the function generator, was achieved. To demonstrate the signal modulation at higher data rates, the inventors employed a continuous wave sinusoidal signal as the data signal. FIG. 5C shows the modulated signal with a 50-GHz carrier, and the calculated power of the signal is shown in FIG. 5D. These results indicate a 6 Gb s⁻¹ data modulation with an ON/OFF switching well below 100 ps. FIG. 13 shows mixing a 15-GHz signal with a 50-GHz carrier, indicating a much faster dynamic performance, with switching times down to 10 ps. FIG. 6 presents the fast Fourier transform (FFT) of the modulated signal presented in FIG. 5C, which demonstrates an excellent multiplication with three pronounced side harmonics.

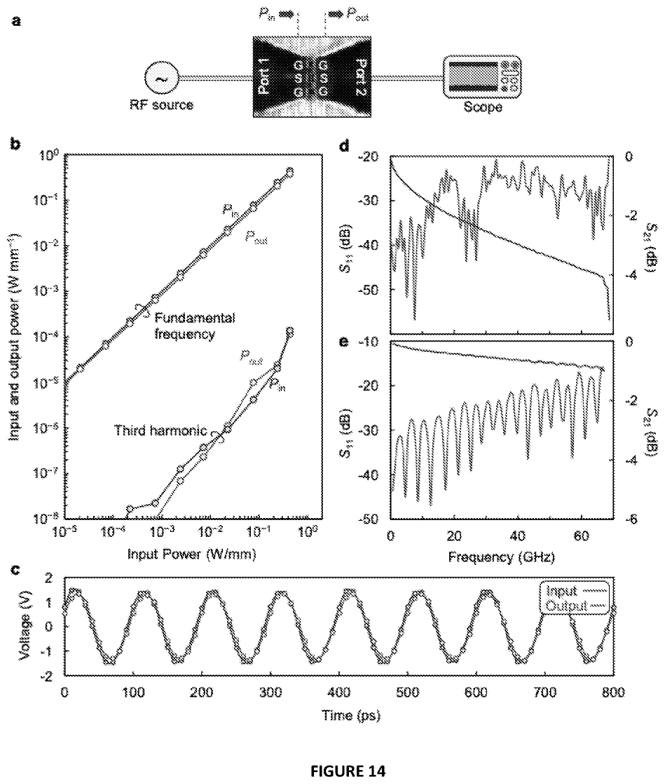

It should be noted that, although the metadevice 1 is an excellent candidate for data modulation and mixing applications thanks to its sharp switching of displacement-fields (FIG. 12), the zero-bias ON state of the device is very linear (FIG. 14). This is due to the fact that the second derivative of channel impedance with respect to the bias voltage is zero at zero bias (FIG. 12). The device also provides a zero static power consumption thanks to its double schottky contact nature. Table 1 (FIG. 16) compares the main properties of metadevices 1 with established radiofrequency switches, showing that the unique features of this device 1 make them very interesting for future ultrahigh-speed electronic systems.

The present disclosure presents the approach of the electronic metadevices 1, in which microscopic manipulation of radiofrequency fields by electrical metastructures 15 leads to outstanding electronic properties in a device form factor. The inventors demonstrate exemplary microwave and terahertz switches, operating based on switching of electric-fields confined in a few-nanometer-thin barrier 7 between a subwavelength metallic metastructure 15 and a high mobility electron sheet 3, which outperforms the state-of-the-art electron devices in multiple figure-of-merits such as the cut-off frequency, contact resistance, and conductance-breakdown voltage trade-off. The metadevice approach is compatible with traditional CMOS and III-V fabrication processes, and has the capacity to be integrated with future monolithic microwave integrated circuits (MMICs) and terahertz monolithic integrated circuits (TMICs). The metadevices 1 can be effectively used as a mixing element with an ultrahigh-speed dynamics which paves the way towards a terahertz-band communications. The high-performance and simplicity of the device 1 offer new horizons for future integrated high-speed electronic and terahertz systems with applications in ultrahigh data-rate transmitters, imaging, sensing and biomedicine, among others.

More details are now provided in relation to the above assessment of the device 1.

### Derivation of Subwavelength TM Mode on a Thin MIS Structure

Assuming a uniform E_{z} at the barrier, the vectorial wave equation ∇×∇×E+ξE=0, in which ξ²=ω²μ₀ε, with ω the angular frequency and μ₀ the vacuum permeability, results in

$$\frac{{\partial }^{2}}{{\partial }^{2} z} {E}_{x} + {ξ}^{2} {E}_{x} = 0 \qquad Eqn . ( 4 )$$

$$\frac{{\partial }^{2}}{{\partial }^{2} x} {E}_{z} - \frac{{\partial }^{2}}{\partial x \partial z} {E}_{z} + {ξ}^{2} {E}_{z} = 0. \qquad Eqn . ( 5 )$$

The solution of (1) can be written as a superposition of e^{jξz} and e^{-jξz}, in which, assuming a deep subwavelength barrier (d), the exponential functions can be linearized. In this case, considering Eₓ(0)=0 and Eₓ(d)=ρJₓ(x), as the boundary conditions imposed by the metal and the semiconductor, respectively, we have Eₓ(x,z)=(ρz/d) Jₓ(x) at the barrier. Substituting this solution into (2) results in (1).

### Device Fabrication

The exemplary microwave and terahertz switches realized based on the metadevice approach were fabricated on an InAlN (5.3 nm)/GaN epitaxy with a 1.1-nm-thin AlN interlayer and 1.1-nm-thin GaN cap layer grown on a Silicon Carbide (SiC—6H) substrate (FIG. 25). After the initial step of substrate cleaning, the sample was coated with a double layer PMMA 495K A8/PMMA 495K A4 electron-beam resists with 7000-rpm and 4500-rpm coating speeds, respectively. The sample was baked at 180° C. for 7:30 after each coating step. Then, an electron-beam lithography step with a dose of 800 μC/cm2 was conducted. The sample was developed in Methyl Isobutyl Ketone (MIBK) combined with Isopropyl Alcohol (IPA) (ratio 1:3) for 3 minutes and then rinsed in IPA for 1 minute. A double layer metallic stack including 50-nm Gold and 30-nm Nickel was deposited, where the Nickel layer was used both for adhesion and forming a schottky contact. A metal lift-off process was conducted in Remover 1165 at 80° C. A photolithography step with nLoF 2020 negative photoresist, following by a 4-min-long Inductively Coupled Plasma (ICP) etching with Chlorine chemistry at 50-W radiofrequency power were used to define the mesa region.

### Radiofrequency Modeling

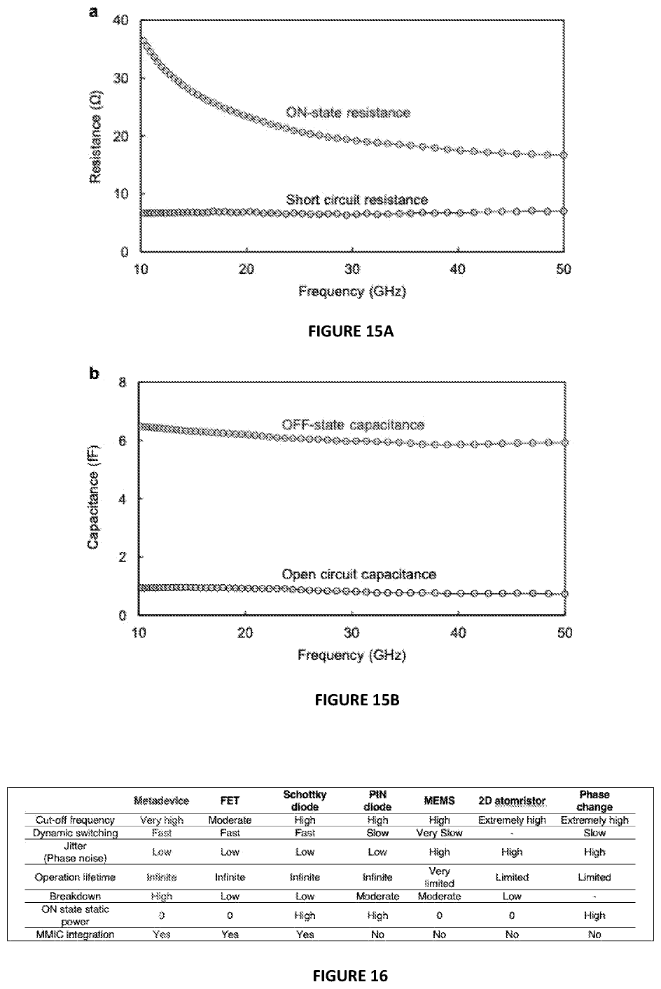

The high-frequency R_{ON} and C_{OFF} were extracted from measured S-parameters using a 50-GHz vector network analyzer (VNA), and a 110-GHz VNA for measurement at higher frequencies. In a two-port measurement, the scattering parameters were measured. Then, the ABCD parameters were extracted from scattering matrix. The parameter B in the ABCD matrix equals the series impedance Z(ω), which is the R_{ON} (in series with a low-impedance imaginary part corresponding to the displacement-field) in the ON state measurement and 1/(jC_{OFF}ω) in the OFF state measurement. The inventors also conducted de-embedding on the measured R_{ON} and C_{OFF}. For each device, a short circuit feature with the same pad size and thickness was fabricated to measure the short-circuit resistance, including two probe-pad contact resistances and also the resistance of metallic pads outside the active area of the device. For the capacitance de-embedding, the inventors measured the capacitance between radiofrequency signal tips of two probes, when they were in separation. The inventors subtracted the short-circuit resistance and open-circuit capacitance from the measured R_{ON} and C_{OFF}. FIG. 15 shows the measured R_{ON} and C_{OFF}, the short circuit and open circuit resistance and capacitance. As a general point, all of the scattering parameter results are presented without any de-embedding.

### Linearity Measurement

An important aspect of a radiofrequency device is its ON-state linearity at high-power regime, which is typically evaluated by the third-order intercept point, so called IP3. FIG. 14B shows the linearity of a 220-nm-long-channel switch in the ON state, where the input signal was supplied at 10 GHz and both the fundamental frequency and the third harmonic of the input (Pᵢₙ) and output (Pₒᵤₜ) were measured. In addition to the very low loss, the switch exhibited a remarkable linearity, along with a high power capability of ˜0.5 W·mm⁻¹, corresponding to a ˜20 dBm input power (limited by the radiofrequency signal source used). The device did not show any notable non-linearity, as the levels of the third harmonic at the input and output of the device are almost equal. In this case, it is not possible to determine the IP3 frequency, as the switch behaves highly linearly. Another sign of high linearity is the lack of signal deformation between the input and output voltage waveforms (FIG. 14C), for fairly large amplitudes.

In the linearity measurement presented in FIG. 12B, the input frequency was set to 10-GHz, and so we limited the bandwidth of oscilloscope to 31-GHz, to capture the fundamental frequency component, as well as the third harmonic at 30-GHz. FIG. 14A shows the experimental set-up for linearity evaluation at high-power regime. The output radiofrequency power was calculated based on the measured voltage waveform at the oscilloscope port v_{osc}

$$\frac{1}{{NZ}_{0}} {\sum }_{n = 1}^{N} {υ}_{osc}^{2} ( {nt}_{s} ) \qquad Eqn . ( 6 )$$

Here Z₀=50Ω is the oscilloscope termination impedance, t_{S}=10 ps is the sampling time, and N=2,000,000 is the captured sample length which includes 200,000 cycles. To measure the input radiofrequency power, the inventors used the same integration on the measured waveform corresponding to a short circuit feature. The losses in the radiofrequency probe (FIG. 14D) and the coaxial cable (FIG. 14E), were de-embedded to obtain the input radiofrequency power Pin. These losses were also de-embedded to achieve the Pout.

### Data Modulation and Mixing Measurement

In the high-data rate modulation and mixing experiments presented in FIG. 5 and FIG. 13 the inventors used the VNA at the continuous-wave single-frequency mode to supply the carrier signal. The VNA had an internal bias tee, and the inventors applied a V_{b}=3.5 V bias voltage to operate the switch close to its threshold voltage. In this case, the excitation voltage applied to the device can be expressed as

$${υ}_{in} = {V}_{bias} + {υ}_{carrier} + {υ}_{message} \qquad Eqn . ( 7 )$$

The device produced the product of v_{carrier} and v_{message}. The output signal was measured using a 70-GHz oscilloscope, and the FFT of the signal was calculated using MATLAB.

The inventors also herein show that the device 1 of the present disclosure can assure the provision of a switch or nano-switch with cut-off frequencies beyond 8 THz for 5G and 6G communications. The rapid progress in high capacity communication systems is reaching extremely high data rates of 100 Gb s⁻¹, which demands electronic switches with cut-off frequencies well above 1 THz. The excellent electron transport properties of III-V heterojunctions could potentially enable terahertz devices, however, the high parasitic capacitances and contact resistances in traditional ultra-scaled electronic devices, such as transistors and diodes, hinder their potential. It is demonstrated here that the fast switching of displacement fields strongly confined in a few-nanometers-thin crystal between a textured metal and an electron sheet, so called displacement-field nano-switch, can provide cut-off frequencies above 8 THz, enabling an efficient switching of terahertz signals. The device offers extremely low ON state resistances approaching 100Ω m, low parasitic capacitances in range of 100 aF μm⁻¹, excellent impedance matching capability, and fast switching times down to 10 ps. The application of these devices is demonstrated for high data rate modulation and mixing. The outstanding performance and integration capability of displacement-field nano-switches pave the way towards mm-wave and terahertz integrated circuits with applications in 5G and 6G communications, among others. Terahertz is a key technology for a wide range of applications, from security and imaging to fundamental sciences [71], [72]. The sixth generation of telecommunications and beyond will be operating at ultrahigh data rates that can reach 100 gigabits per second, requiring efficient and robust terahertz switches for data modulation [73]. Conventional electronic and optical devices, however, fail to operate efficiently at this frequency range, which defines a so-called terahertz gap [74]. This significantly hinders the development of the next generation of radiofrequency systems, highlighting the need for new ultrahigh speed devices to bridge the spectrum gap between microwave and optical frequencies.

As previously mentioned, the evolution of high-speed conventional electronic devices has relied on an extreme shrinkage of the device dimensions, which, as a consequence increases the relative weight of the parasitic components on the device performance. This trade-off poses a limit on the effectiveness of further scaling. The performance of ultra-scaled devices is hindered by the tunneling through contacts and high parasitic capacitances. Schottky barrier diodes with regrown contacts [75] are the fastest electronic device up to date, presenting cut-off frequencies of about 3 THz in wafer scale [76]. The inventors herein demonstrate that the excellent field coupling between a micro-textured metal 15 and a two-dimensional electron gas (2DEG), a few nanometers apart from each other, provides an excellent metal-semiconductor contact, breaking the trade-off between ON resistance (R_{ON}) and OFF capacitance (C_{OFF}). Devices 1 are demonstrated with R_{ON} approaching 100Ω·μm, cut-off frequencies beyond 8 THz, and excellent dynamic performance with a switching time down to 10 ps. These results make them an outstanding candidate for future high speed electronics.

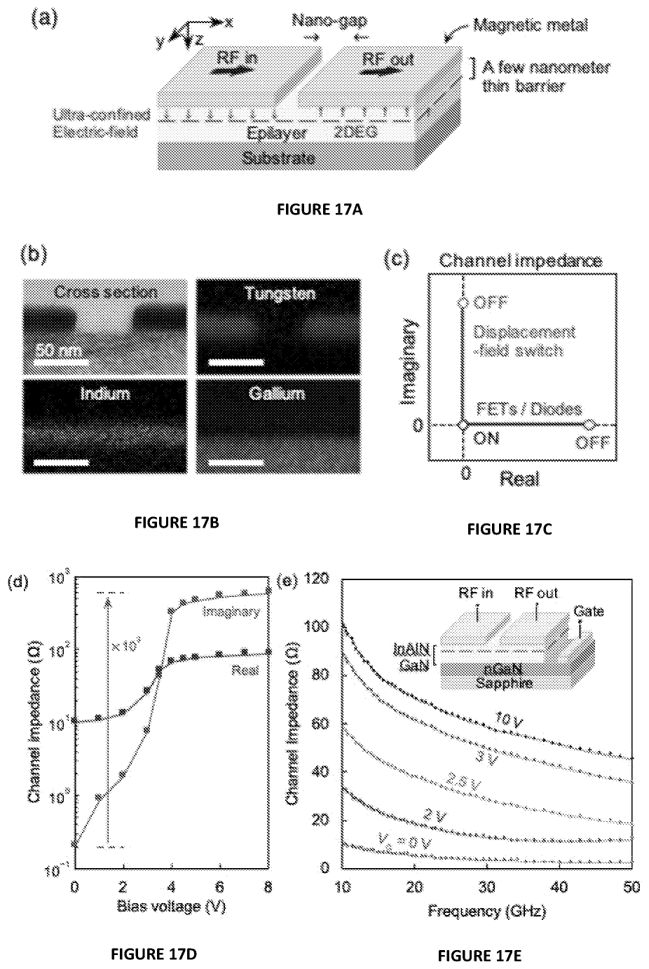

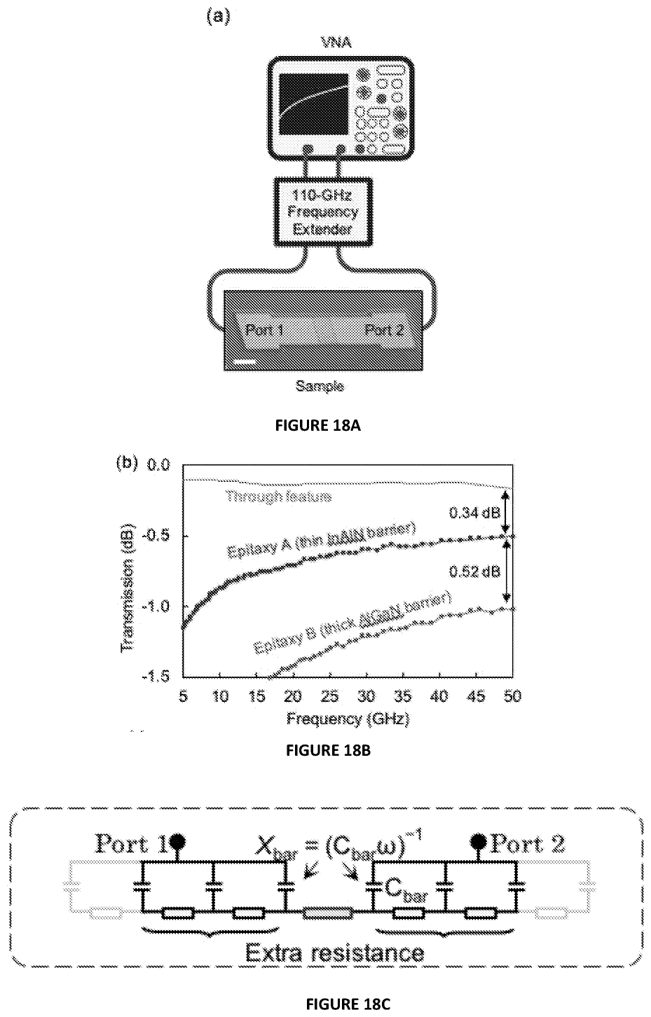

FIG. 17A shows a schematic of a displacement-field nano-switch including a nano-gap formed by two identically-shaped metallic pads on a high-electron-mobility heterojunction with a thin barrier. At direct-current (dc) regime, the device provides isolation between the two ports, so no static power is dissipated. A high-frequency signal, however, can be transmitted from one port to another, thanks to the strong electric-field coupling between the metal and the floating 2DEG. This coupling is drastically enhanced by replacing the simple straight-edge pads by a microstructured metal 15, leading to an outstandingly low resistance with very small parasitics. By applying a control signal to one of the ports, the 2DEG at the interface is depleted, eliminating the electric-field coupling, which turns OFF the switch. The simple and self-aligned fabrication in which the entire device is patterned in a single lithography step enables ultra-scaling the channel length to below 50 nm (FIG. 17B).

FIG. 17C shows the channel impedance during a switching event in a conventional field-effect transistors (FETs) and diodes and in a displacement-field nano-switch 1. Traditional devices switch ohmic currents along the real axis. Alternatively, displacement-field nano-switch switch displacement currents along the imaginary axis. FIG. 17D presents the measured channel impedance of a displacement-field nano-switch for different bias voltages, indicating three orders of magnitude switching in the imaginary component of the impedance. The switch can be also implemented as a three-port device by adding a gate electrode, either as a back-gate (FIG. 17E), or as a typical top-gate between the two contacts.

The scattering (S) parameters of displacement-field nano-switches fabricated on two different epitaxies were measured using a vector network analyzer (VNA) (FIG. 18A). Epitaxy A is composed of InAlN/GaN with a 7.5-nm-thin barrier, and epitaxy B has an AlGaN/GaN heterostructure with a 27-nm-thin barrier. In both cases, Au (50 nm)/Ni (50 nm) contacts with 320 nm-long gap were used. Both epitaxies present almost identical sheet resistance of ˜300Ω/□, however, the thin-barrier epitaxy (A) yields a much lower insertion loss, indicating the superior metal-2DEG coupling (FIG. 18B). This shows the critical role of field confinement in the barrier, which can be explained based on the distributed circuit model (FIG. 2C).

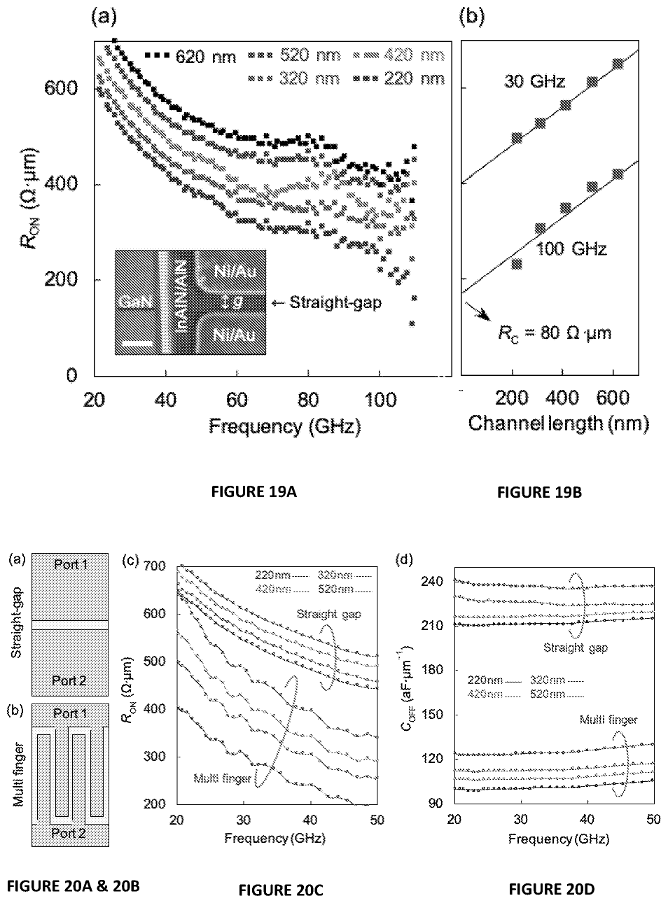

A stronger field confinement, which can be achieved with thinner barriers or at higher frequencies, results in a smaller barrier reactance, thus concentrating the current density closer to the gap (FIG. 18C). This effectively reduces the impact of ohmic resistance of metals on the device resistance. Based on the S parameters, the inventors extracted the R_{ON} of devices with different gap lengths fabricated on epitaxy A, up to 110 GHz (FIG. 19A). These results show the reduction of R_{ON} for smaller gaps and as the frequency increases due to the smaller barrier reactance, reaching values below 200Ω·μm at 110 GHz. From these measurements, an effective contact resistance of R_{C}=80Ω·μm at 100 GHz was extracted from transfer length method (TLM) (FIG. 19B).

Designing displacement-field devices 1 with multiple narrow fingers 17A, 17B (microstructured devices 1), with similar gap length, can drastically change the current density distribution and enhance the device performance by breaking the trade-off between R_{ON} and C_{OFF}. FIGS. 20A and 20B show the two geometries of displacement-field switches 1 of this disclosure. The normalized R_{ON} and C_{OFF} measured at 50 GHz (FIGS. 20C and 20D, respectively) reveal that the multi-finger devices 1 exhibit more than two times lower resistance, and about two times lower capacitance compared to the straight-gap device. One notes that the entire width of the gap in the multi-finger structure 15 was considered in the normalization, although the R_{ON}C_{OFF} product, which is 4 times lower in the multi-finger devices 1, is a self-normalized parameter and clearly shows the superior performance of multi finger devices 1.

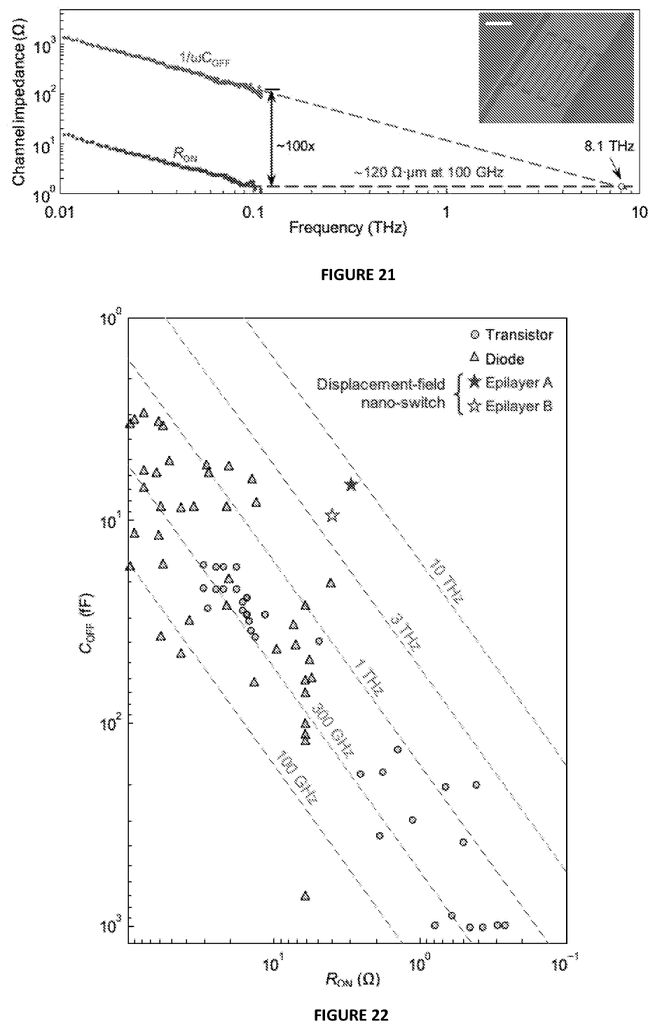

While a cut-off frequency (f_{c}=½πR_{ON}C_{OFF}) of 1.5 THz was obtained for 220-nm-long straight-gap devices, multi-finger devices 1 with the same gap length presented an outstandingly higher value of 6.2 THz. The R_{ON} of multi finger devices 1 further decreases at higher frequencies, reaching an ultralow value of 120Ω·μm at 100 GHz (FIG. 21), corresponding to a cut-off frequency of 8.1 THz. The extreme field confinement, and the multi finger device geometry, drastically boosted the performance of displacement-field nano-switches 1 with respect to previous capacitively-coupled contacts [77], such as metal-2DEG-metal varactors [78], which provide cut-off frequencies below 2 THz. The ultralow resistance of microstructured metal 15 to a semiconductor can be a universal approach, offering an alternative to nonalloyed or semi-metal contacts at high frequencies [79][80][81].

FIG. 22 benchmarks the R_{ON} and C_{OFF} obtained for multi finger displacement-field nano-switches 1 fabricated on epitaxies A (solid star) and B (hollow star). The devices 1 are no longer limited by the metal-semiconductor tunneling resistance, and thanks to their high conductance and low parasitic capacitance, exhibit cut-off frequencies much higher than conventional devices such as diodes and transistors. Such a superior performance offer great prospects for high speed electronics with applications in high data-rate signal modulation and mixing, as presented in the following section.

Displacement-field nano-switches 1 also exhibit a promising matching capability without requiring extra matching networks.

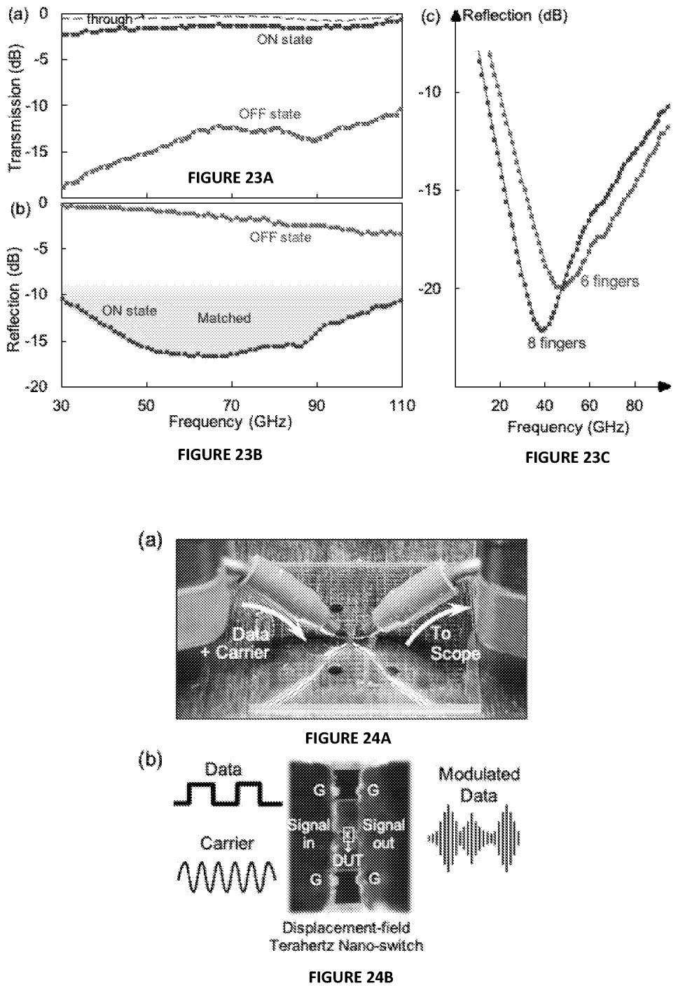

FIGS. 23Aa and 23B show the transmission and reflection of a multi finger switch 1. The device exhibits a 0.6 dB insertion loss and ON/OFF ratio of 10 dB at 110 GHz, and provides a good matching in a very wide frequency range from 30 GHz to 110 GHz. The range of impedance matching can be easily tuned by a layout design (FIG. 23C).

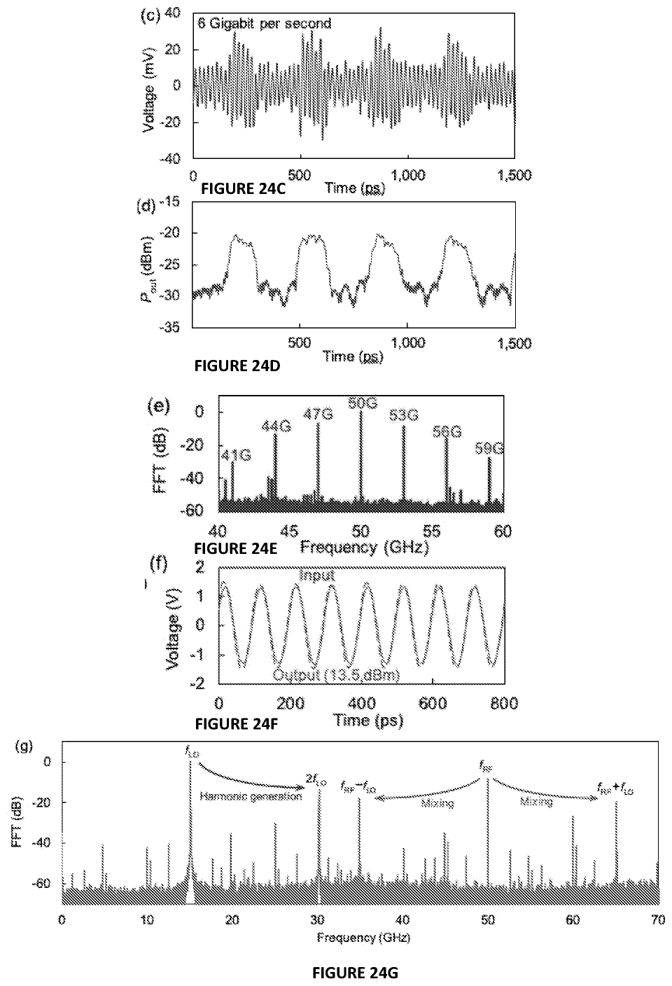

Displacement-field nano-switches 1 also provide an excellent dynamic performance and show ultrafast switching between ON and OFF states, which enable ultrahigh-speed data transmission. FIGS. 24A and 24B show the experimental set-up to demonstrate the dynamic behavior of the proposed devices. A local oscillator (LO) generates a carrier signal, which is combined with a base-band data signal, and applied to one port of a displacement-field nano-switch 1. The switch 1 was biased close to the threshold voltage, at 3.5 V. The second terminal was terminated by a 50-Ω port of a 70-GHz oscilloscope, to measure the modulated signal.

To show the signal modulation at high data rates, the inventors employed a continuous wave sinusoidal signal as the data signal. FIG. 24C shows the modulated signal with a 50-GHz carrier, and the calculated spontaneous power of the signal is shown in FIG. 24D. These results reveal a 6 Gb s¹ data modulation with an ON/OFF switching well below 100 ps. FIG. 24E presents the fast Fourier transform (FFT) of the modulated signal presented in FIG. 24C, which shows an excellent multiplication with three pronounced side harmonics. The switch 1 can linearly operate at high power signal levels (FIG. 24F). Displacement-field nano-switches are also excellent candidates for mixing applications. FIG. 24E shows mixing a 15-GHz large signal LO with a 50-GHz RF signal, indicating a very fast dynamic performance, with a switching time down to 10 ps.

Displacement-field nano-switches 1 provide an excellent coupling between a textured metallic contact and a 2DEG, breaking the trade-off between R_{ON} and C_{OFF}. It is demonstrated that this device 1 with a relatively long channel length (>200 nm) enables an ultralow total R_{ON} of 120Ω·μm along with extremely high cut-off frequencies beyond 8 THz. The devices 1 are compatible with common planar fabrication methods and can be integrated on III-V platforms as part of the future high-speed electronic circuits. The simplicity and high performance of the proposed devices pave the way toward high frequency integrated systems, with application in 5G, 6G, among others.

The inventors carried out further evaluations of the device 1 as a terahertz electronic metadevice and further evaluations of the frequency figure-of-merit FOM. Different metadevices were realized designed for operation in microwave, millimeter-wave (mm-wave), and terahertz bands (Table 1 of FIG. 27) on a high-electron-mobility InAlN/GaN platform. As shown in FIG. 28A, the devices were characterized based on two-port complex scattering parameter measurements at microwave, mm-wave, and terahertz frequencies (FIG. 28B). For a terahertz electronic metadevice with 8 stripes (inset of FIG. 28C), the ON-state resistance (R_{ON}) and OFF-state capacitance (C_{OFF}) extracted from scattering parameter measurements up to 1 THz show extremely high cutoff frequency FOM of 18 THz, which agrees well with simulations (FIG. 28C). FIG. 28D benchmarks microwave, mm-wave, and terahertz metadevices with different number of stripes on a C_{OFF}-R_{ON} plane, which indicates f_{CO} values much higher than those achieved by traditional devices. This benchmark also reveals two major features of metadevices. First, the device performance becomes better at higher frequencies, as terahertz metadevices significantly outperform microwave devices: the cutoff frequency FOM of terahertz devices evaluated at 1 THz is notably higher than that of microwave switches evaluated at 50 GHz. This is due to the fact that the subwavelength λ_{sub} becomes shorter at higher frequencies which enables a higher confinement of current in the semiconductor channel, and therefore results in a higher conductance. Second, increasing the number of stripes can enhance the device performance. This originates from the collective interaction between the subwavelength mode and the stripe array that becomes more pronounced with larger number of stripes, and therefore the conductance of metadevices grows super-linearly, while the increase in OFF-state capacitance is still linear. Scaling conventional devices reduces R_{ON} and increases C_{OFF} at the same rate, so that the f_{CO} remains constant. The metadevice 1 breaks this trade off by further reducing the resistance which outbalances the linear increase in C_{OFF} and results in notably higher f_{CO}.

In addition to the very low resistance of the metadevices in the ON state, experiments and simulations show extremely high linearity, mainly because of two reasons. First, due to the symmetry of the devices, applying a positive or a negative voltage with identical magnitudes have the same impact on the device impedance. In other words, the second derivative of the impedance at zero bias is zero. Second, the transmissive mode is quite resilient against partial depletion under the stripe array. Simulations show almost constant electrical properties until a ˜50% depletion at the metal-semiconductor junction and measurements indicate very small variations in the resistance for bias voltages in range of −3 V to +3V. Outside this range, the device undergoes a dramatic switching where the imaginary part of the impedance plays a major role. The insights from the microscopic patterns of radiofrequency fields in the ON and OFF states as well as the switching behavior enabled to develop a compact circuit model for the proposed devices (FIG. 29).

A compact circuit model for the electronic metadevices 1 is presented in FIGS. 29A to 29G. The model consists of the following elements:
1. The channel resistance R_{ch}: This part can be considered to be constant with respect to frequency and voltage. It represents the pure resistive impedance corresponding to the semiconductor channel. For a metadevice with effective width W_{eff} and gap g, we have R_{ch}=gW_{eff}⁻¹Rₛₕ, where Rₛₕ is the sheet resistance of the semiconductor layer.
2. The series resistance R_{S}: This part models the losses due to the presence of current in the semiconductor outside the gap (equivalent to the summation of contact resistances from the two sides of the channel). The contact resistance drops with increasing the frequency and ultimately can become insignificant compared to R_{ch} at high frequencies. R_{S} is a function of voltage, and becomes larger while switching OFF the device. This happens due to the depletion of the semiconductor layer under one terminal.
3. The series reactance X_{S}=L_{S}ω−(C_{S}ω)⁻¹: This part represents the reactive impedance due to the metal-semiconductor coupling, as well as parasitic inductances, which can be modeled by a series resonator tank. We can re-write X_{S} as

$${Y}_{S} = {Z}_{0 S} ( \frac{ω}{{ω}_{0 S}} - \frac{{ω}_{0 S}}{ω} ) \qquad ( 20 )$$

Where ω_{0S}=(L_{S}C_{S})^{-1/2} and Z_{0S}=(L_{S}/C_{S})^{1/2} represent the central frequency and the characteristic impedance of the resonator. We note that X_{S}(ω_{0S})=0, and X_{S} could be very small (negligible compared to R_{ch}) for a wide range of frequencies, if Z_{0S} is low impedance.

Based on simulations, X_{S} plays the dominant role in the switching transient. In this case, switching the vertical displacement field at the barrier totally changes the state of the device. The inventors model this effect by considering a voltage dependence of the series capacitor, C_{S}(V), where V is the voltage across the device. Due to the symmetry of the proposed devices, C_{S}(V) is an even function (C_{S}(V)=C_{S}(−V)).
4. The parallel capacitance C_{P}: Even without having the semiconductor layer, the stripe array has a capacitance, like interdigital capacitors. So C_{P} is a linear capacitance parallel to the device terminals. In fact, both C_{S} and C_{P} contribute to the OFF-state capacitance of the device (C_{OFF}), however, at moderate voltage biases, where only a small portion of the channel is depleted, C_{S} can dominate C_{P}. So in applications like modulators, where the device does not hold very large voltages, only the series impedance

$${Z}_{S} = R \text{?} + R \text{?} ( V ) + j ( 2 πf L \text{?} - \frac{1}{2 π {fC}_{S} ( V )} ) \qquad ( 21 )$$

$$\text{?} \text{indicates text missing or illegible when filed}$$

can be an accurate representation of the device impedance.

The inventors evaluated the proposed circuit model in a metadevice with 8 stripes (L=10.8 μm, W=1.28 μm, g=320 nm). Based on S-parameter measurements we extracted the capacitance and the inductance of the switch, from 0 to 10 V (FIG. 29D). Since C_{S} dominates C, at moderate voltages, the inventors assigned the entire extracted capacitance to C_{S}. The capacitance was almost flat up to ˜3 V, and then showed an abrupt change. We empirically fitted the obtained values by

$${C}_{S} ( V ) = \frac{260}{1 + \frac{1}{25} \frac{\vert V \vert}{{V}_{th}} + {( \frac{V}{{V}_{th}} )}^{20}} + 9.5 fF , \qquad ( 22 )$$

where Vₜₕ=4.3 V is the threshold voltage. The series inductance was quite small and only affected the device impedance in the ON state, were it showed the voltage-independent value of 50 pH. As shown in FIG. 29E, considering the resonance frequency (˜43 GHz), the fixed value of L_{S} together with the fitted capacitance, well describe the device impedance for a large voltage swing, from −10 V to +10 V.

The real part of the impedance (R_{ON}=R_{ch}+R_{S}) was fitted by

$${R}_{ON} ( V ) = 6.5 + \frac{45}{1 + {( V / {V}_{th} )}^{- 10}} Ω \qquad ( 23 )$$

The model works well for a broad range of frequencies. FIG. 29F shows a very good agreement between the modeled reactance (solid lines) and measurements (discrete points) in both ON and OFF states. The series inductance X_{S} is negligible compared to R_{ON} for a wide range of frequencies (˜20% bandwidth), which shows the wide-band nature of the transmissive mode. FIG. 29F also indicates that R_{ON} can be practically considered to be frequency independent. This is because R_{ON} is almost flat for high frequencies, and for low frequencies, X_{S} totally dominates R_{ON}. So X_{S} can solely describe the impedance at low frequencies. In this case, one can assume a fixed value for R_{ON} (corresponding to that of high frequencies).

An important feature of the proposed devices is that they exhibit different impedances at low and high Frequency. The transmissive mode offers very low impedances in a wide frequency window. At intermediate frequencies, however, X_{S} becomes large. This can be highly beneficial for the switching performance of the device. For example, schottky diodes exhibit almost identical impedances for low and high frequencies: in this case if the device achieves a low insertion loss at high frequencies, then a high power control signal is needed to switch ON and OFF the device. In metadevices, however, the control signal sees a rather high impedance while the carrier signal sees a low impedance. Considering the frequencies within a 10% bandwidth channel around the resonance frequency, all the different kinds of metadevices realized (microwave, mm-wave, and terahertz devices) show high impedances (Z_{IF}>>50Ω) (FIG. 29G).

The results obtained by the S-parameter measurements, which were captured by the circuit model, show a great correlation to the microscopic features of the device. In particular, the following points:
1. The device exhibits a very flat response in the ON state. At the highly transmissive mode, the reactive part of the impedance is totally negligible and the measured resistance is almost constant in a large voltage swing between −3 V to +3 V. This level of linearity is an important feature of the proposed devices which is originated from their very fundamental working principle. This is a great benefit for RF switching, since the device does not produce harmonics in the ON state.
2. The switching is mainly driven by X_{S} and it is quite dramatic close to the threshold voltage. This is also in agreement with the simulations which showed that X_{S} plays the most important role in the switching mechanism. The abrupt switching reflects in the steep functionality of C(V) presented in equation (22).
3. The transmissive mode is quite wide-band which is reflected in the simulations where the manipulation of E_{z} can be seen in a wide range of frequencies, leading to current confinement.
4. The devices exhibit high impedances for intermediate frequencies, which is highly beneficial for large signal switching. If we apply

$${υ}_{in} ( t ) = {A}_{IF} cos ( {ω}_{IF} t ) + {a}_{RF} cos ( {ω}_{RF} t ) \qquad ( 24 )$$

to the first port (A_{IF} and a_{RF} represent the amplitudes of the intermediate frequency (IF) and RF signals with angular frequencies of ω_{IF} and ω_{RF}) and terminate the second port by a load, then the RF signal will be transmitted without producing a considerable voltage across the terminals (because the device has a low impedance). For the IF signal, however, most of the amplitude A_{IF} will drop across the terminals which switch ON and OFF the device. This is not the case in schottky diodes, for example, were a strong IF signal is needed to switch the device.

Additionally, concerning contact resistance and quantum resistance, as previously mentioned, one of the limitations for conventional ultra-scaled semiconductor devices is their large resistance of ohmic contacts. The state-of-the-art tunneling junctions, which are widely used in transistors and diodes, exhibit contact resistance (R_{C}) values larger than ˜30Ω μm, which by itself is equal to the resistance of a 100-nm long channel on a semiconductor with a sheet resistance of 300Ω/. So in the case of ultra-scaled devices, contact resistances totally dominate the semiconducting channel. FIG. 30A shows the contact resistance versus the total ON-state resistance of metadevices (based on scattering parameter measurements at higher frequencies) comparing to those reported for traditional devices. Electronic metadevices can outperform tunneling junctions, and in case of metadevices operating at terahertz frequencies, a very low contact resistance of ˜10Ω m has been achieved. The devices also show very low total ON-state resistance (R_{ON}) values approaching the quantum limit of resistance in 2D channel semiconductor devices. Such a low resistance can play a key role to enable not only high-performance terahertz switches, but also terahertz amplifiers with very large transconductances in a three-terminal device form factor.

The inventors examined further the breakdown characteristics of electronic metadevices. FIG. 30B benchmarks the specific conductance (G_{SP}) of metadevices 1 with respect to their breakdown voltage. The specific conductance is defined as the conductance (G) divided by the channel area (G_{SP}=GW_{eff}g⁻¹). Carrier density and electron mobility together with the critical electric field impose a fundamental trade-off between conductance and breakdown voltage in semiconductor devices. In a lateral device, this trade-off is determined by the sheet resistance, contact resistance, and the critical electric field. The ideal device line in FIG. 30B assumes a zero contact resistance, while the other dashed line indicates the maximum conduction considering the state-of-the-art R_{C}=30Ω μm. The proposed metadevices 1 outperform the best traditional devices in the literature, enabling the device performance to approach the ideal device limit determined by the semiconductor material. FIG. 30C presents the breakdown voltage versus cutoff frequency FOM of electronic metadevices, which shows almost two orders of magnitude increase in V_{BR}×f_{CO} with respect to traditional devices. This resolves a key challenge in terahertz electronics, as traditional terahertz devices can only handle very low voltages of only a few volts while electronic metadevices with cutoff frequency FOM of 18 THz can withstand 30 V.

The inventors also further implemented the device 1 of the present disclosure as a high-speed terahertz modulator. One application of electronic metadevice 1 is a modulator. Mapping an electrical signal onto a THz carrier which shows the potential for ultrahigh capacity telecommunication links. As presented in FIG. 31A, in a two-terminal scheme, the data signal is applied to one port of a metadevice 1 integrated with coplanar waveguides. A terahertz continuous wave is injected to the second port of the device. The data signal controls the state of the metadevice 1, and correspondingly changes the reflection of the THz wave. The reflected wave is separated from the incident carrier by a directional coupler and goes to a coherent THz receiver which down-converts the signal to the intermediate frequency (IF). FIG. 31B shows received signals with different carrier frequencies, along with the eye diagram of the 520.4 GHz channel shown in FIG. 31C. The corresponding spectra presented in FIG. 31D shows that the precise modulation by metadevices 1 can provide a platform for ultra-dense allocation of communication channels which enables massive THz wireless networks. The inventors examined the modulation efficiency of the system at very high stream data rates. The data signal was replaced by a sinusoidal source which represents a consecutive sequence of “01”. FIG. 31E shows the normalized modulation efficiency at the carrier frequency of 0.55 THz which indicates a flat response up to very high data rates, showcasing the operation in the THz band.

Ultrafast low-jitter switching dynamic is an important advantage of terahertz switches realized by the metadevice approach with respect to other technologies such as micro-electro-mechanical systems (MEMS), phase-change materials, and 2D memristors. The high-speed modulation achieved by electronic metadevices 1 indicates their picosecond switching capability. The speed of the measurements is currently limited by the state-of-the-art experimental setup. The results presented here show the great potential for terahertz applications.

The inventors also evaluated the switching performance of electronic metadevices under harsh conditions, at high voltages and high speeds. This is important since trapped carriers under high-voltage stresses can potentially degrade the (trans)conductance of lateral devices. The experiments up to 20 V (corresponding to electric fields on the order of one megavolts per centimeter), showed very good dynamic performance, even though the device was not passivated. The inventors believe that the different operation principle of electronic metadevices 1, with respect to conventional devices, can explain such a superior dynamic performance: the effect of trapped carriers can be modeled by an effective electrostatic potential which partially depletes the 2DEG. The resilience of the transmissive mode against partial channel depletions suggests that such trapped carriers cannot have a major effect on the device performance.

The device 1 and results presented herein show that electronic metadevices 1 challenge the limitations of traditional semiconductor device and extend the operation of electronics to higher speeds, larger voltages, and higher efficiencies. The high-performance of metadevice terahertz switches 1 demonstrated herein potentially offers a large impact on ultrafast electronics and can enable ultrahigh-speed telecommunication systems covering the entire THz band. In a more general view, the electronic metadevice approach can enable variety of functional devices such as gain elements and rectifiers on any material system, ranging from CMOS to 2D materials, with performances far surpassing the state-of-the-art in classic electronics.

While the invention has been disclosed with reference to certain preferred embodiments, numerous modifications, alterations, and changes to the described embodiments, and equivalents thereof, are possible without departing from the sphere and scope of the invention.

Accordingly, it is intended that the invention not be limited to the described embodiments and be given the broadest reasonable interpretation in accordance with the language of the appended claims. The features of any one of the above described embodiments may be included in any other embodiment described herein.

### REFERENCES

1. del Alamo, J. A. Nanometre-scale electronics with III-V compound semiconductors. Nature 479, 317-323 (2011).
2. Chau, R., Doyle, B., Datta, S., Kavalieros, J. & Zhang, K. Integrated nanoelectronics for the future. Nature Mater. 6, 810-812 (2007).
3. Shen, P. C. et al. Ultralow contact resistance between semimetal and monolayer semiconductors, Nature 593, 211-217 (2021).
4. Sengupta, K., Nagatsuma, T. & Mittleman, D. M. Terahertz integrated electronic and hybrid electronic-photonic systems. Nat. Electron. 1, 622-635 (2018).
5. Samizadeh Nikoo, M. et al. Nanoplasma-enabled picosecond switches for ultrafast electronics. Nature 579, 534-539 (2020).
6. Mehdi, I., Siles, J. V., Lee, C. & Schlecht, E. THz diode technology: status, prospects, and applications. Proc. IEEE 105, 990-1007 (2017).
7. Guo, J. et al. MBE regrown ohmics in InAlN HEMTs with a regrowth interface resistance of 0.05 ohm-mm. IEEE Electron Device Lett. 33, 525-527 (2012).
8. Shinohara, K. et al. Self-aligned-gate GaN-HEMTs with heavily-doped n+-GaN ohmic contacts to 2DEG, in Proc. IEEE IEDM, 27.2.1-27.2.4 (2012).
9. Tang, Y. et al. Ultrahigh-Speed GaN High-Electron-Mobility Transistors with fT/fmax of 454/444 GHz. IEEE Electron Device Lett. 36, 549-551 (2015).
10. Allain, A., Kang, J., Banerjee, K. & Kis, A. Electrical contacts to two-dimensional semiconductors. Nat. Mater. 14, 1195-1205 (2015).
11. Yu, X., Zhou, J., Qi, C., Cao, Z., Kong, Y. & Chen, T. A high frequency hydrogen-terminated diamond MISFET with fT/fmax of 70/80 GHz. IEEE Electron Device Lett. 39, 1373-1376 (2018).
12. Johnson, E. O. Physical limitation on frequency and power parameters of transistors. In IEEE International Convention Record 27-34 (IEEE, 1965).
13. Dang, S. Amin, O. Shihada, B. & Alouini, M.-S. What should 6G be? Nat. Electron. 3, 20-29 (2020).
14. Koenig, S. et al. Wireless sub-THz communication system with high data rate. Nat. Photonics 7, 977-981 (2013).
15. Suzuki, D., Oda, S. & Kawano, Y. A flexible and wearable terahertz scanner. Nat. Photonics. 10, 809-814 (2016).
16. Ivanov, R., Stantchev, Yu, X. Blu, T. & Pickwell-MacPherson, E. Real-time terahertz imaging with a single-pixel detector. Nat. Commun. 11, 2535 (2020).
17. Liu, H.-B. et al. Terahertz spectroscopy and imaging for defense and security applications. Proc. IEEE 95, 1514-1527 (2007).
18. Vakil, A. & Engheta, N. Transformation optics using graphene. Science 332, 1291-1294 (2011).
19. Pendry, J. B., Schurig, D. & Smith, D. R. Controlling electromagnetic fields. Science 312, 1780-1782 (2006).
20. Pendry, J. B. Negative refraction makes a perfect lens. Phys. Rev. Lett. 85, 3966-3969 (2000).
21. Alu, A. & Engheta, N. Achieving transparency with plasmonic and metamaterial coatings. Phys. Rev. E 95, 016623 (2005).
22. Grant, P. D., Denhoff, M. W. & Mansour, R. R. A Comparison between RF MEMS Switches and Semiconductor Switches. in 2004 International Conference on MEMS, NANO and Smart Systems (ICMENS'04), 2004, 515-521.
23. Hwang, J. H., Lee, G., Nouman, M. T., Cha, S., Hong S., & Jang, J. Self-aligned metal-semiconductor-metal varactors based on the AlGaN/GaN heterostructure, IEEE Electron Device Letters 40, 1740-1743 (2019).
24. Madan, H. et al. 26.5 Terahertz electrically triggered RF switch on epitaxial V02-on-sapphire (VOS) wafer. In 2015 IEEE International Electron Devices Meeting (IEDM) 9.3.1-9.3.4 (IEEE, Washington, D C, 2015).
25. Kim, M. et al. Zero-static power radio-frequency switches based on MoS2 atomristors. Nat. Commun. 9, 2524 (2018).
26. Kim, M. et al. Analogue switches made from boron nitride monolayers for application in 5G and terahertz communication systems. Nat. Electron. 3, 479-485 (2020).
27. del Valle, J. et al. Spatiotemporal characterization of the field-induced insulator-to-metal transition. Science 373, 907 (2021).
28. Puglisi, F. M. et al. M. 2D h-BN based RRAM devices. 2016 IEEE International Electron Devices Meeting (IEDM); IEEE, Dec. 3-7, 2016, 34.8.1-34.8.4.
29. Ruijing, G. et al. A library of atomically thin 2D materials featuring the conductive-point resistive switching phenomenon, Adv. Mater. 33, 2007792 (2021).
30. Krestinskaya, O., James, A. P. & Chua, L. O. Neuro-memristive circuits for edge computing: a review. IEEE Trans. Neural Netw. Learn. Syst. 1, 1-20 (2019).
31. Siles J. V. & Grajal, J. Physics-based design and optimization of Schottky diode frequency multipliers for terahertz applications. IEEE Trans. Microw. Theory Tech. 58, 1933-1942 (2010).
32. B. Romanczyk, W. Li, M. Guidry, N. Hatui, A. Krishna, C. Wurm, S. Keller, & U. K. Mishra, N-Polar GaN-on-sapphire deep recess HEMTs with high W-band power density. IEEE Electron Device Lett. 41, 1633-1636 (2020).
33. S. Makioka, Y. Anda, K. Miyatsuji, & D. Ueda, Super self-aligned GaAs RF switch IC with 0.25 dB extremely low insertion loss for mobile communication systems. IEEE Trans. Electron Devices 48, 1510-1514 (2001).
34. D. Kelly, C. Brindle, C. Kemerling, & M. Stuber, The state-of the-art of silicon-on-sapphire CMOS RF switches. in Proc. CSIC, 200-202 (2005).
35. C. Campbell & D. Dumka, Wideband high power GaN on SiC SPDT switch MMICs. in Proc. IEEE MTT-S Int. Microw. Symp. Dig., 145-148 (2010).
36. X. Zheng, M. Guidry, H. Li, B. Romanczyk, E. Ahmadi, K. Hestroffer, S. Wienecke, S. Keller, & U. K. Mishra. N-polar GaN MISHEMTs on sapphire with a proposed figure of merit fmax VDS,Q of 9.5 THz.V. In 75th Annual Device Research Conference 1-2 (IEEE, 2017).
37. Y. Tsukahara, T. Katoh, Y. Notani, T. Ishida, T. Ishikawa, M. Komaru, & Y. Matsuda, Millimeter-wave MMIC switches with pHEMT cells reduced parasitic inductance. in IEEE MTT-S Int. Microwave Symp. Dig., 1295-1298 (2003).
38. H. Kamitsuna, Y. Yamane, M. Tokumitsu, H. Sugahara, & M. Muraguchi, Low-power InP-HEMT switch ICs integrating miniaturized 2×2 switches for 10-Gb/s systems. IEEE J. Solid-State Circuits 41, 452-460 (2006).
39. Q. Xiao, G. Samiotes, T. Galluccio, & B. Rizzi, A high performance DC-20 GHz SPDT switch in a low cost plastic QFN package. in Proc. Eur. Microw. Conf, 320-323 (2009).
40. S. Sankaran and K. K. O. Schottky diode with cutoff frequency of 400 GHz fabricated in 0.18 m CMOS. Electron. Lett. 41, 506-508 (2005).
41. S. Sankaran & K. K. O. Schottky barrier diodes for millimeter wave detection in a foundry CMOS process. IEEE Electron Devices Lett. 26, 492-494, (2005).
42. Y. Lee, J. R. East, & L. P. Katehi, High-efficiency W-band GaAs monolithic frequency multipliers. IEEE Trans. Microw. Theory Tech. 52, 529-535 (2004).
43. G. Santoruvo, M. Samizadeh Nikoo, & E. Matioli, Broadband Zero-Bias RF Field-Effect Rectifiers Based on AlGaN/GaN Nanowires. IEEE Microw. Wireless Compon. Lett. 30, 66-69, (2020).
44. U. R. Pfeiffer, C. Mishra, R. M. Rassel, S. Pinkett, & S. K. Reynolds, Schottky barrier diode circuits in silicon for future millimeter-wave and terahertz applications. IEEE Trans. Microw. Theory Tech. 56, 364-371 (2008).
45. S. Liang, L. Zhang, Z. Zhang, Z. Feng, H. Guo, D. Xing, G. Gu, Y. Fang, & J. Wang, GaN planar Schottky barrier diode with cut-off frequency of 902 GHz. Electron. Lett. 52, 1408-1410 (2016).
46. K. W. Kobayashi, R. Kasody, A. K. Oki, S. Dow, B. Allen, & D. C. Streit, K-Band double balanced mixer using GaAs HBT THz Schottky diodes. in IEEE MTT-S Int. Microw. Symp. Dig., 1163-1166 (1994).
47. S. Mizojiri et al., GaN Schottky barrier diode for sub-terahertz rectenna. in Proc. IEEE Wireless Power Transfer. Conf, 36-39 (2019).
48. J. Ma, C. Erine, M. Zhu, N. Luca, P. Xiang, K. Cheng, and E. Matioli, “1200 V Multi-channel power devices with 2.8Ω·mm ON-resistance,” in IEDM Tech. Dig. IEEE Int. Electron Devices 1-4 (2019).
49. D. Lee, X. Gao, S. Guo, D. Kopp, P. Fay, & T. Palacios, 300-GHz InAlN/GaN HEMTs with InGaN back barrier. IEEE Electron Device Lett. 32, 1525-1527 (2011).
50. Y. Yue, Z. Hu, J. Guo, B. Sensale-Rodriguez, G. Li, R. Wang, F. Faria, T. Fang, B. Song, X. Gao, S. Guo, T. Kosel, G. Snider, P. Fay, D. Jena, and H. Xing, InAlN/AlN/GaN HEMTs with regrown ohmic contacts and fT of 370 GHz. IEEE Electron Device Lett. 33, 988-990 (2012).
51. M. Higashiwaki, T. Mimura, & T. Matsui, 30-nm-gate AlGaN/GaN heterostructure field-effect transistors with a current-gain cutoff frequency of 181 GHz. Jpn. J. Appl. Phys. 45, L1 111-L1 113 (2006).
52. F. Medjdoub, M. Zegaoui, B. Grimbert, D. Ducatteau, N. Rolland, & P.-A. Rolland, First demonstration of high-power GaN-on-silicon transistors at 40 GHz. IEEE Electron Device Lett. 33, 1168-1170 (2012).
53. J. Lei, J. Wei, G. Tang, and J. K. Chen, Reverse-blocking AlGaN/GaN normally-off MIS-HEMT with double-recessed gated Schottky drain. in Proc. Int. Symp. Power Semiconductor Devices ICs (ISPSD), 13-17 (2018).
54. S. Maroldt, R. Quay, C. Haupt, R. Kiefer, D. Wiegner, & O. Ambacher, Integrated-Schottky-diode GaN HFET for high-efficiency digital PA MMICs at 2 GHz. in Proc. Eur. Microw. Conf., 636-639 (2010).
55. E. Bahat-Treidel, R. Lossy, J. Wurfl, & G. Trankle, AlGaN/GaN HEMT with integrated recessed Schottky-drain protection diode. IEEE Electron Device Lett. 30, 901-903 (2009).
56. H. F. Sun, A. R. Alt, H. Benedickter, C. R. Bolognesi, E. Feltin, J. F. Carlin, M. Gonschorek, N. Grandjean, T. Maier, and R. Quay, 102-GHz AlInN/GaN HEMTs on silicon with 2.5-W/mm output power at 10 GHz. IEEE Electron Device Lett. 30, 796-798 (2009).
57. A. L. Corrion, K. Shinohara, D. Regan, I. Milosavljevic, P. Hashimoto, P. J. Willadsen, A. Schmitz, D. C. Wheeler, C. M. Butler, D. Brown, S. D. Burnham, & M. Micovic, Enhancement-mode AlN/GaN/AlGaN DHFET with 700-mS/mm gm and 112-GHz fT. IEEE Electron Device Lett. 31, 1116-1118 (2010).
58. D. Denninghoff, J. Lu, E. Ahmadi, S. Keller, & U. K. Mishra, “N-polar GaN/InAlN/AlGaN MIS-HEMTs with 1.89 S/mm extrinsic transconductance, 4 A/mm drain current, 204 GHz fT and 405 GHz fiax. in Proc. 71st DRC, 197-198 (2013).
59. K. Shinohara, D. Regan, I. Milosavljevic, A. L. Corrion, D. F. Brown, P. J. Willadsen, C. Butler, A. Schmitz, S. Kim, V. Lee, A. Ohoka, P. M. Asbeck, & M. Micovic, Electron velocity enhancement in laterally-scaled GaN DH-HEMTs with fT of 260 GHz. IEEE Electron Device Lett. 32, 1074-1077 (2011).
60. K. D. Chabak, M. Trejo, A. Crespo, D. E. Walker, J. Yang, R. Gaska, M. Kossler, J. K. Gillespie, G. H. Jessen, V. Trimble, & G. D. Via, Strained AlInN/GaN HEMTs on SiC with 2.1-A/mm output current and 104-GHz cutoff frequency. IEEE Electron Device Lett., 31, 561-563 (2010).
61. R. Wang, G. Li, G. Karbasian, J. Guo, B. Song, Y. Yue, Z. Hu, O. Laboutin, Y. Cao, W. Johnson, G. Snider, P. Fay, D. Jena, & H. G. Xing, Quaternary barrier InAlGaN HEMTs with fT/fmax of 230/300 GHz. IEEE Electron Device Lett. 34, 378-380 (2013).
62. R. Wang, G. Li, G. Karbasian, J. Guo, B. Song, Y. Yue, Z. Hu, O. Laboutin, Y. Cao, W. Johnson, G. Snider, P. Fay, D. Jena, & H. G. Xing, Quaternary barrier InAlGaN HEMTs with fT/fmax of 230/300 GHz. IEEE Electron Device Lett. 34, 378-380 (2013).
63. D. S. Lee, O. Laboutin, Y. Cao, W. Johnson, E. Beam, A. Ketterson, M. Schuette, P. Saunier, D. Kopp, P. Fay, & T. Palacios. 317 GHz InAlGaN/GaN HEMTs with extremely low on-resistance. Phys. Status Solidi C, Current Topics Solid State Phys. 10, 827-830 (2013).
64. R. Wang, G. Li, J. Verma, B. Sensale, T. Fang, J. Guo, Z. Y. Hu, O. Laboutin, Y. Cao, W. Johnson, G. Snider, P. Fay, D. Jena, & H. Xing. 220-GHz quaternary barrier InAlGaN/AlN/GaN HEMTs. IEEE Electron Device Lett. 32, 1215-1217 (2011).
65. D. C. Dumka, T. M. Chou, F. Faili, D. Francis, & F. Ejeckam, AlGaN/GaN HEMTs on diamond substrate with over 7 W/mm output power density at 10 GHz. Electron. Lett. 49, 1298-1299, (2013).
66. D. Marti, S. Tirelli, A. R. Alt, J. Roberts, & C. R. Bolognesi, 150 GHz cutoff frequencies and 2 W/mm output power at 40 GHz in a millimeter wave AlGaN/GaN HEMT technology on silicon. IEEE Electron Device Lett. 33, 1372-1374 (2012).
67. F. Lecourt, N. Ketteniss, H. Behmenburg, N. Defrance, V. Hoel, M. Eickelkamp, A. Vescan, C. Giesen, M. Heuken, & J. De Jaeger, InAlN/GaN HEMTs on sapphire substrate with 2.9-W/mm output power density at 18 GHz. IEEE Electron Device Lett. 32, 1537-1539 (2011).
68. G. Xie, E. Xu, J. Lee, N. Hashemi, B. Zhang, F. Y. Fu, & W. T. Ng, Breakdown-voltage-enhancement technique for RF-based AlGaN/GaN HEMTs with a source-connected air-bridge field plate. IEEE Electron Device Lett. 33, 670-672 (2012).
69. S. Arulkumaran, S. Vicknesh, G. I. Ng, Z. H. Liu, M. Bryan, & C. H. Lee. Low Specific On-Resistance AlGaN/AlN/GaN High Electron Mobility Transistors on High Resistivity Silicon Substrate. Electrochem. Solid-State Lett. 13, H169-H172 (2010).
70. J. W. Johnson, E. L. Piner, A. Vescan, R. Therrien, P. Rajagopal, J. C. Roberts, J. D. Brown, S. Singhal, & K. J. Linthicum. 12 W/mm AlGaN-GaN HFETs on silicon substrates. IEEE Electron. Device Lett. 25, 459-461 (2004).
71. K. Sengupta, T. Nagatsuma, and D. M. Mittleman, Nature Electron. 1, 622-635, 2018.
72. T. S. Rappaport et al., IEEE Access 7, 78729-57, 2019.
73. S. Dang, et al. Nat. Electron. 3, 20-29, 2020.
74. M. Tonouchi, Nat. Photon. 1, 97-105, 2007.
75. K. Shinohara et al. IEEE Trans. Electron Devices 60, 2982-2996, 2013.
76. B. T. Bulcha et al. IEEE Trans. THz Sci. Technol. 6, 737-746, 2016.
77. A. Koudymov et al. IEEE Electron Device Lett. 30, 478-480, 2009.
78. J. H. Hwang et al. IEEE Electron Device Lett. 40, 1740-1743, 2019.
79. K. J. Chen, et al. IEEE Trans. Electron Devices. 43, 252-257, 1996.
80. S. Dasgupta, et al. Appl. Phys. Lett. 96, 143504, 2010.
81. P.-C. Shen, et al., Nature 593, 211-217, 2021.

1-49. (canceled)

50. An electronic metadevice comprising
at least one conductive channel configured to provide charge carriers;
at least one metal layer superposed on the at least one conductive channel; and
a barrier layer located between the at least one metal layer and the at least one conductive channel;
wherein the at least one metal layer includes at least one recess extending through the at least one metal layer to define at least one metallic metastructure comprising at least one first metal layer portion adjacent to at least one second metal layer portion; and
wherein the at least one recess extends through the at least one metal layer to define (i) a micro-structured or a nano-structured at least one first metal layer portion comprising at least one first metallic finger extending away from a first support of the at least one first metal layer portion towards the at least one second metal layer portion; and (ii) a micro-structured or a nano-structured at least one second metal layer portion comprising at least one second metallic finger extending away from a second support of the at least one second metal layer portion towards the at least one first metal layer portion; the at least one first metallic finger being located adjacent to the at least one second metallic finger.

51. The electronic metadevice according to claim 50, wherein the at least one recess extends through the at least one metal layer to define (i) a plurality of first metallic fingers extending away from the first support of the at least one first metal layer portion towards the at least one second metal layer portion; and (ii) a plurality of second metallic fingers extending away from the second support of the at least one second metal layer portion towards the at least one first metal layer portion (11A); the first metallic fingers (17A) being located adjacent to the second metallic fingers (17B).

52. The electronic metadevice according to claim 50, wherein the at least one recess extends through the at least one metal layer to define (i) a micro-structured or a nano-structured at least one first metal layer portion comprising a plurality of first metallic fingers; and (ii) a micro-structured or a nano-structured at least one second metal layer portion comprising at least one second metallic extension; the first metallic finger being located adjacent to the second metallic finger.

53. The electronic metadevice according to claim 50, wherein the at least one recess extends through the at least one metal layer in a winding or meandering manner to define a plurality of interleaving metallic fingers separated by the at least one recess.

54. The electronic metadevice according to claim 50, wherein the barrier layer is a current barrier configured to restrict or prevent current flow therethrough during operation of the semiconductor device.

55. The electronic metadevice according to claim 50, wherein the barrier layer is configured to assure a strong electric field coupling between the at least one metal layer and the at least one conductive channel.

56. The electronic metadevice according to claim 50, wherein the at least one metal layer and the barrier layer are configured to support transverse magnetic modes that interact with the at least one metal layer to permit current density confinement.

57. The electronic metadevice according to claim 50, wherein the barrier layer has a thickness supporting subwavelength transverse magnetic modes that interact with the at least one metal layer to permit current density confinement.

58. The electronic metadevice according to claim 50, wherein the at least one recess extends through the at least one metal layer to define at least one metallic finger (17A) of the at least one first metal layer portion and at least one depression of the at least one second metal layer portion, the at least one metal finger being surrounded by the at least one depression.

59. The electronic metadevice according to claim 50, wherein the at least one recess extends to define a plurality of metallic fingers of the at least one first metal layer portion and a plurality of depressions of the at least one second metal layer portion, the metal fingers being surrounded by the depressions.

60. The electronic metadevice according to the claim 59, wherein the at least one recess extends through the at least one metal layer to define at least one metallic finger of the at least one second metal layer portion and at least one depression of the at least one first metal layer portion, the at least one metal finger being surrounded by the at least one depression.

61. The electronic metadevice according to claim 60, wherein the at least one recess extends to define a plurality of metallic fingers of the at least one second metal layer portion and a plurality of depressions of the at least one first metal layer portion, the metal fingers being surrounded by the depressions.

62. The electronic metadevice according to claim 50, wherein the first and second metal layer portions comprise a plurality of interleaving metallic fingers separated by the at least one recess.

63. The electronic metadevice according to claim 50, wherein the at least one recess defines a separation gap distance g between the at least one first metal layer portion and the at least one second metal layer portion.

64. The electronic metadevice according to claim 63, wherein the separation gap distance g is substantially the same as the at least one recess extends through the at least one metal layer to define the at least one first metal layer portion and the at least one second metal layer portion.

65. The electronic metadevice according to claim 50, wherein the at least one recess extends fully through the at least one metal layer.

66. The electronic metadevice according to claim 50, wherein the first metal layer portion is separated or fully separated from the second metal layer portion by the at least one recess.

67. The electronic metadevice according claim 50, wherein the first metal layer portion is solely indirectly in physical contact with the second metal layer portion via barrier layer.

68. The electronic metadevice according to claim 50, wherein the at least one conductive channel is defined by a semiconductor heterojunction defined by at least one first semiconductor material and at least one second semiconductor material.

69. The electronic metadevice according to claim 50, including a plurality of input ports, and at least one or a plurality of output ports, and
wherein the plurality of input ports is configured to apply multiple voltages to the semiconductor device to control a signal transmission between input and output ports.
